(19) United States
(12) Patent Application Publication
(10) Pub. No.: US 2025/0374764 A1
(43) Pub. Date: Dec. 4, 2025

(54) DISPLAY DEVICE

(71) Applicant: Samsung Display Co., LTD., Yongin-si (KR)

(72) Inventors: Yong Hee LEE, Yongin-si (KR); Kyung Bae KIM, Yongin-si (KR); Dong Woo KIM, Yongin-si (KR); Yeon Kyung KIM, Yongin-si (KR)

(21) Appl. No.: 19/078,124

(22) Filed: Mar. 12, 2025

(30) Foreign Application Priority Data
Jun. 4, 2024 (KR) 10-2024-0073165

(51) Int. Cl. H10K 59/121; G09G 3/3233; H10K 59/131

(52) U.S. Cl. CPC H10K 59/1216; H10K 59/131; G09G 3/3233; G09G 2300/0426; G09G 2300/0819; G09G 2300/0852; G09G 2300/0861

(57) ABSTRACT

The present disclosure relates to a display device with improved image quality. The display device may include a substrate, a light-emitting element above the substrate, a transistor connected to the light-emitting element, a first node connected to a gate electrode of the transistor, and a capacitor connected between the first node and a second node, and including a first capacitor electrode connected to the first node and including first sub-capacitor electrodes, and a second capacitor electrode connected to the second node, and including second sub-capacitor electrodes at a same layer as the first sub-capacitor electrodes, wherein one of the first sub-capacitor electrodes is between adjacent ones of the second sub-capacitor electrodes.

### CROSS-REFERENCE TO RELATED APPLICATION

The present application claims priority to, and the benefit of, Korean Patent Application No. 10-2024-0073165, filed on Jun. 4, 2024, in the Korean Intellectual Property Office, the entire disclosure of which is incorporated herein by reference.

### BACKGROUND

### 1. Field

The present disclosure relates to a display device with improved image quality.

### 2. Description of the Related Art

A head-mounted display (HMD) is an image display device that is worn on a user's head in the form of glasses or a helmet and forms a focus at a distance close to user's eyes in front of the user's eyes. The head-mounted display may implement virtual reality (VR) or augmented reality (AR).

The head-mounted display magnifies and displays an image displayed by a small display device using a plurality of lenses. Therefore, a display device applied to the head-mounted display needs to provide a high-resolution image, for example, an image having a resolution of about 3000 pixels per inch (PPI) or more. To this end, an organic light-emitting diode on silicon (OLEDoS), which is a small organic light-emitting display device having a relatively high resolution, has been used as the display device applied to the head-mounted display. The OLEDOS is a device that displays an image by disposing organic light-emitting diodes (OLEDs) on a semiconductor wafer substrate on which complementary metal oxide semiconductors (CMOSs) are arranged.

### SUMMARY

Aspects of the present disclosure provide a display device with improved image quality.

According to an aspect of the present disclosure, there is provided a display device including a substrate, a light-emitting element above the substrate, a transistor connected to the light-emitting element, a first node connected to a gate electrode of the transistor, and a capacitor connected between the first node and a second node, and including a first capacitor electrode connected to the first node and including first sub-capacitor electrodes, and a second capacitor electrode connected to the second node, and including second sub-capacitor electrodes at a same layer as the first sub-capacitor electrodes, wherein one of the first sub-capacitor electrodes is between adjacent ones of the second sub-capacitor electrodes.

The first sub-capacitor electrodes may include a first outermost sub-capacitor electrode and a second outermost sub-capacitor electrode at respective sides of the first sub-capacitor electrodes, wherein the second sub-capacitor electrodes include a third outermost sub-capacitor electrode and a fourth outermost sub-capacitor electrode at respective sides of the second sub-capacitor electrodes.

The first sub-capacitor electrodes may be between the third outermost sub-capacitor electrode and the fourth outermost sub-capacitor electrode.

The first outermost sub-capacitor electrode may be between the third outermost sub-capacitor electrode and the fourth outermost sub-capacitor electrode.

The second outermost sub-capacitor electrode may be between the third outermost sub-capacitor electrode and the fourth outermost sub-capacitor electrode.

The first outermost sub-capacitor electrode and the third outermost sub-capacitor electrode may be adjacent to each other.

The second outermost sub-capacitor electrode and the fourth outermost sub-capacitor electrode may be adjacent to each other.

The display device may further include a first data line adjacent to the third outermost sub-capacitor electrode.

The third outermost sub-capacitor electrode may be between the first data line and the first outermost sub-capacitor electrode.

The display device may further include a second data line adjacent to the fourth outermost sub-capacitor electrode.

The third outermost sub-capacitor electrode may be between the second outermost sub-capacitor electrode and the second data line.

The first capacitor electrode may further include third sub-capacitor electrodes above the first sub-capacitor electrodes, and connected to the first sub-capacitor electrodes, and fourth sub-capacitor electrodes below the first sub-capacitor electrodes, and connected to the first sub-capacitor electrodes.

The first data line may include a first sub-data line at a same layer as the first sub-capacitor electrodes, and a second sub-data line at a same layer as the third sub-capacitor electrodes, and connected to the first sub-data line.

The second capacitor electrode may further include fifth sub-capacitor electrodes above the second sub-capacitor electrodes, and connected to the second sub-capacitor electrodes, and sixth sub-capacitor electrodes below the second sub-capacitor electrodes, and connected to the second sub-capacitor electrodes.

The third sub-capacitor electrodes and the fifth sub-capacitor electrodes may be at a same layer.

The fourth sub-capacitor electrodes and the sixth sub-capacitor electrodes may be at a same layer.

The first capacitor electrode may further include seventh sub-capacitor electrodes above the third sub-capacitor electrodes, and connected to the third sub-capacitor electrodes.

The first data line may include a first sub-data line at a same layer as the first sub-capacitor electrodes, and a second sub-data line at a same layer as the third sub-capacitor electrodes, and connected to the first sub-data line.

An end of a connection portion where the first sub-capacitor electrodes are connected to each other may be above a same straight line as an end of an outermost one of the second sub-capacitor electrodes in plan view.

An extension direction of the first sub-capacitor electrodes may be parallel to an extension direction of the second sub-capacitor electrodes.

According to an aspect of the present disclosure, there is provided an electronic device including a display device including a substrate, a light-emitting element above the substrate, a transistor connected to the light-emitting element, a first node connected to a gate electrode of the transistor, and a capacitor connected between the first node and a second node, and including a first capacitor electrode connected to the first node and including first sub-capacitor electrodes, and a second capacitor electrode connected to the second node, and including second sub-capacitor electrodes at a same layer as the first sub-capacitor electrodes, wherein one of the first sub-capacitor electrodes is between adjacent ones of the second sub-capacitor electrodes

The electronic device may include a smartphone, a television, a monitor, a tablet, an electric vehicle, a mobile phone, a tablet personal computer (PC), a mobile communication terminal, an electronic notebook, an electronic book, a portable multimedia player (PMP), a navigation device, an ultra-mobile PC (UMPC), a laptop computer, a billboard, an Internet of Things (IoT) device, a smartwatch, a watch phone, or a head-mounted display (HMD).

With a display device according to one or more embodiments, image quality may be improved.

The aspects of the present disclosure are not limited to the above-described effects and other aspects that are not described herein will become apparent to those skilled in the art from the following description.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view illustrating the display device according to one or more embodiments;

FIG. 2 is a block diagram illustrating the display device according to one or more embodiments;

FIG. 3 is an equivalent circuit diagram of a first pixel according to one or more embodiments;

FIG. 4 is a layout diagram illustrating an example of a display panel according to one or more embodiments;

FIGS. 5 and 6 are layout diagrams illustrating embodiments of a display area of FIG. 4;

FIG. 7 is a cross-sectional view illustrating an example of the display panel taken along line 11-11′ of FIG. 5;

FIG. 8 is a plan view of a first-first sub-capacitor electrode of a first capacitor electrode, a second-first sub-capacitor electrode of a second capacitor electrode, a third-first sub-capacitor electrode of a third capacitor electrode, a fourth-first sub-capacitor electrode of a fourth capacitor electrode, and a third connection electrode;

FIG. 9 is a plan view of a first-second sub-capacitor electrode of the first capacitor electrode, a second-second sub-capacitor electrode of the second capacitor electrode, a third-second sub-capacitor electrode of the third capacitor electrode, a fourth-second sub-capacitor electrode of the fourth capacitor electrode, and a first sub-data line;

FIG. 10 is a plan view of a first-third sub-capacitor electrode of the first capacitor electrode, a second-third sub-capacitor electrode of the second capacitor electrode, a third-third sub-capacitor electrode of the third capacitor electrode, a fourth-third sub-capacitor electrode of the fourth capacitor electrode, and a second sub-data line;

FIG. 11 is a plan view of a first-fourth sub-capacitor electrode of the first capacitor electrode, a second-fourth sub-capacitor electrode of the second capacitor electrode, a third-fourth sub-capacitor electrode of the third capacitor electrode, and a fourth-fourth sub-capacitor electrode of the fourth capacitor electrode;

FIG. 12 is a cross-sectional view illustrating an example of the display panel taken along line 12-12′ of FIGS. 8 to 11;

FIG. 13 is an enlarged view of area A of FIG. 9;

FIG. 14 is a view for describing an arrangement of sub-capacitor electrodes between a plurality of data lines adjacent to each other;

FIG. 15 is a cross-sectional view of a display panel according to one or more other embodiments;

FIG. 16 is a cross-sectional view of a display panel according to still one or more other embodiments;

FIG. 17 is a cross-sectional view of a display panel according to still one or more other embodiments;

FIG. 18 is a view illustrating one or more other embodiments of a sub-capacitor electrode in the display device according to one or more embodiments;

FIG. 19 is a perspective view illustrating a head-mounted display device according to one or more embodiments;

FIG. 20 is an exploded perspective view illustrating an example of the head-mounted display device of FIG. 19; and

FIG. 21 is a perspective view illustrating a head-mounted display according to one or more other embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

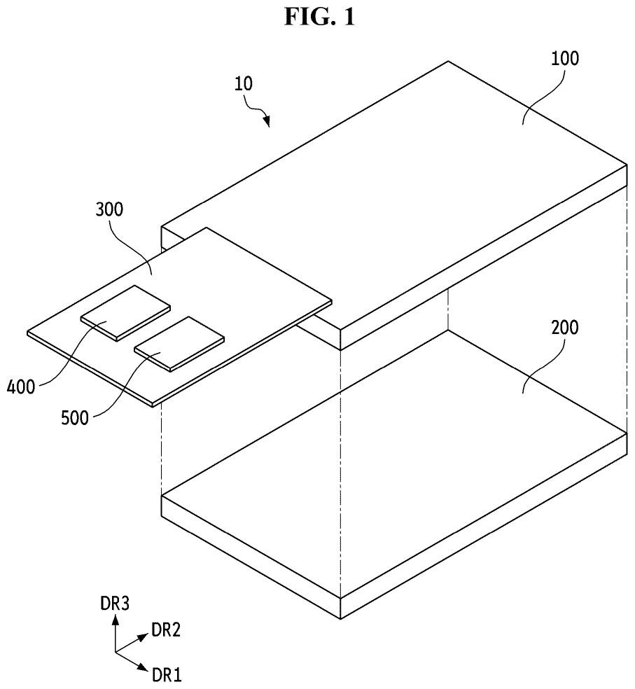

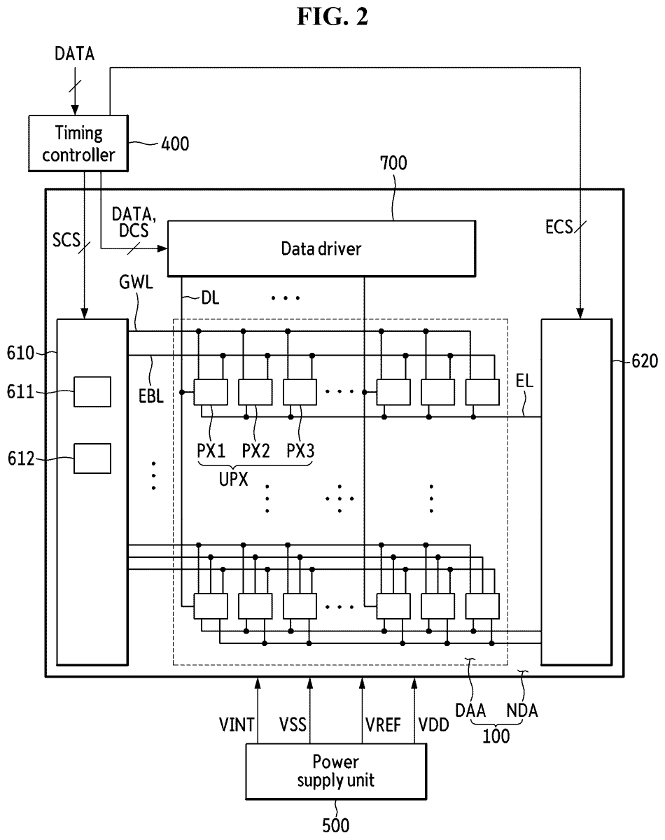

FIG. 1 is an exploded perspective view illustrating the display device according to one or more embodiments. FIG. 2 is a block diagram illustrating the display device according to one or more embodiments.

Referring to FIGS. 1 and 2, a display device 10 according to one or more embodiments is a device that displays a moving image or a still image. The display device 10 according to one or more embodiments may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 according one or more embodiments may be applied as a display unit of televisions, laptop computers, monitors, billboards, or the Internet of Things (IOTs). Alternatively, the display device 10 according one or more embodiments may be applied to smart watches, watch phones, or head-mounted displays (HMDs) for implementing virtual reality and augmented reality.

The display device 10 according to one or more embodiments includes a display panel 100, a heat dissipation layer 200, a circuit board 300, a timing controller 400, and a power supply unit 500.

The display panel 100 may have a shape similar to a rectangular shape in plan view. For example, the display panel 100 may have a shape similar to a rectangular shape, in plan view, having short sides in a first direction DR1 and long sides in a second direction DR2 crossing the first direction DR1. In the display panel 100, a corner where the short side in the first direction DR1 and the long side in the second direction DR2 meet may be rounded with a curvature (e.g., predetermined curvature) or right-angled. A shape of the display panel 100 in plan view is not limited to the rectangular shape, and may be a shape similar to other polygonal shapes, a circular shape, or an elliptical shape. A shape of the display device 10 in plan view may follow the shape of the display panel 100 in plan view, but one or more embodiments of the present disclosure is not limited thereto.

The display panel 100 may include a display area DAA that displays an image and a non-display area NDA that does not display an image, as illustrated in FIG. 2.

The display area DAA includes a plurality of pixels PX, a plurality of scan lines GWL and EBL, a plurality of emission control lines EL, and a plurality of data lines DL.

The plurality of pixels PX may be arranged in a matrix form in the first direction DR1 and the second direction DR2. The plurality of scan lines GWL and EBL and the plurality of emission control lines EL may extend in the first direction DR1 and may be located in the second direction DR2. The plurality of data lines DL may extend in the second direction DR2, and may be located in the first direction DR1.

The plurality of scan lines GWL and EBL include a plurality of write scan lines GWL and a plurality of bias scan lines EBL.

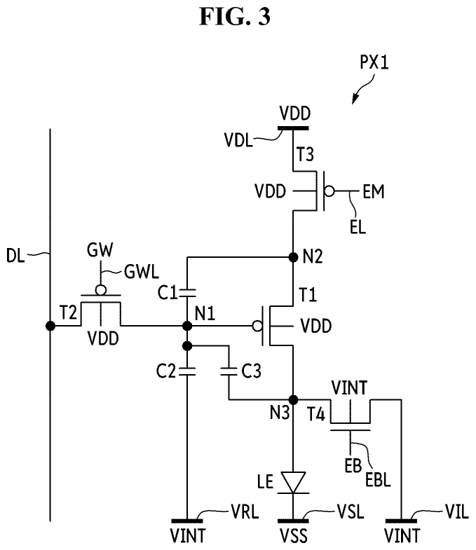

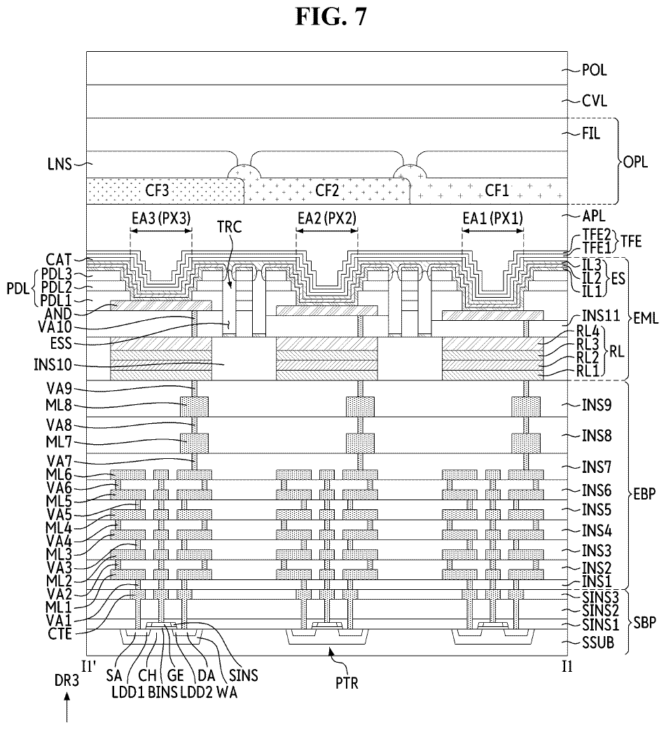

A plurality of unit pixels UPX include a plurality of pixels PX1, PX2, and PX3. The plurality of pixels PX1, PX2, and PX3 may include a plurality of pixel transistors as illustrated in FIG. 3, and the plurality of pixel transistors may be formed by a semiconductor process, and may be located on a semiconductor substrate SSUB (see FIG. 7). As used herein, “located on” may mean “above.” For example, a plurality of pixel transistors of a data driver 700 may be formed as complementary metal oxide semiconductors (CMOSs).

Each of the plurality of pixels PX1, PX2, and PX3 may be connected to any one of the plurality of write scan lines GWL, any one of the plurality of bias scan lines EBL, any one of the plurality of emission control lines EL, and any one of the plurality of data lines DL. Each of the plurality of pixels PX1, PX2, and PX3 may receive a data voltage of the data line DL according to a write scan signal of the write scan line GWL, and allow a light-emitting element to emit light according to the data voltage.

The non-display area NDA includes a scan driver 610, an emission driver 620, and a data driver 700.

The scan driver 610 includes a plurality of scan transistors, and the emission driver 620 includes a plurality of light-emitting transistors. The plurality of scan transistors and the plurality of light-emitting transistors may be formed by a semiconductor process and formed on a semiconductor substrate SSUB (see FIG. 7). For example, the plurality of scan transistors and the plurality of light-emitting transistors may be formed as CMOSs. It has been illustrated in FIG. 2 that the scan driver 610 is located on the left side of the display area DAA and the emission driver 620 is located on the right side of the display area DAA, but one or more embodiments of the present disclosure is not limited thereto. For example, the scan drivers 610 and the emission drivers 620 may be located on both the left and right sides of the display area DAA.

The scan driver 610 may include a write scan signal output unit 611 and a bias scan signal output unit 612. Each of the write scan signal output unit 611 and the bias scan signal output unit 612 may receive a scan-timing control signal SCS from the timing controller 400. The write scan signal output unit 611 may generate write scan signals according to the scan-timing control signal SCS of the timing controller 400 and sequentially output the write scan signals to the write scan lines GWL. The bias scan signal output unit 612 may generate bias scan signals according to the scan-timing control signal SCS and sequentially output the bias scan signals to the bias scan lines EBL.

The emission driver 620 may generate emission control signals according to an emission-timing control signal ECS and sequentially output the emission control signals to the emission control lines EL.

The data driver 700 may include a plurality of data transistors, and the plurality of data transistors may be formed by a semiconductor process and formed on a semiconductor substrate SSUB (see FIG. 7). For example, the plurality of data transistors may be formed as CMOSs.

The data driver 700 may receive digital video data DATA and a data-timing control signal DCS from the timing controller 400. The data driver 700 converts the digital video data DATA into analog data voltages according to the data-timing control signal DCS, and outputs the analog data voltages to the data lines DL. In this case, the pixels PX1, PX2, and PX3 may be selected by the write scan signals of the scan driver 610, and the data voltages may be supplied to the selected pixels PX1, PX2, and PX3.

The heat dissipation layer 200 may overlap the display panel 100 in a third direction DR3, which is a thickness direction of the display panel 100. The heat dissipation layer 200 may be located on one surface, for example, a rear surface, of the display panel 100. The heat dissipation layer 200 serves to dissipate heat generated from the display panel 100. The heat dissipation layer 130 may include a layer made of graphite or metal such as silver (Ag), copper (Cu), or aluminum (Al) having high thermal conductivity.

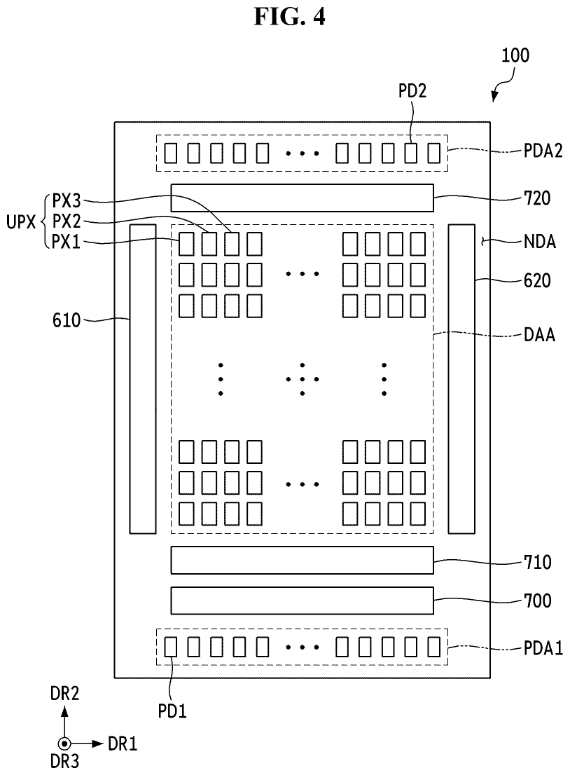

The circuit board 300 may be electrically connected to a plurality of first pads PD1 (see FIG. 4) of a first pad unit PDA1 (see FIG. 4) of the display panel 100 using a conductive adhesive member, such as an anisotropic conductive film. The circuit board 300 may be a flexible printed circuit board or a flexible film having a flexible material. It has been illustrated in FIG. 1 that the circuit board 300 is unbent, but the circuit board 300 may be bent. In this case, one end of the circuit board 300 may be located on the rear surface of the display panel 100 and/or a rear surface of the heat dissipation layer 200. One end of the circuit board 300 may be an end opposite to the other end of the circuit board 300 connected to the plurality of first pads PD1 (see FIG. 4) of the first pad unit PDA1 (see FIG. 4) of the display panel 100 using the conductive adhesive member.

The timing controller 400 may receive digital video data and timing signals from the outside. The timing controller 400 may generate the scan-timing control signal SCS, the emission-timing control signal ECS, and the data-timing control signal DCS for controlling the display panel 100 according to the timing signals. The timing controller 400 may output the scan-timing control signal SCS to the scan driver 610, and may output the emission-timing control signal ECS to the emission driver 620. The timing controller 400 may output the digital video data and the data-timing control signal DCS to the data driver 700.

The power supply unit 500 may generate a plurality of panel driving voltages according to an external source voltage. For example, the power supply unit 500 may generate a common voltage VSS, a driving voltage VDD, and an initialization voltage VINT, and may supply the common voltage VSS, the driving voltage VDD, and the initialization voltage VINT to the display panel 100. The common voltage VSS, the driving voltage VDD, and the initialization voltage VINT will be described later with reference to FIG. 3.

Each of the timing controller 400 and the power supply unit 500 may be formed as an integrated circuit (IC), and may be attached to one surface of the circuit board 300. In this case, the scan-timing control signal SCS, the emission-timing control signal ECS, the digital video data DATA, and the data-timing control signal DCS of the timing controller 400 may be supplied to the display panel 100 through the circuit board 300. In addition, the common voltage VSS, the driving voltage VDD, and the initialization voltage VINT of the power supply unit 500 may be supplied to the display panel 100 through the circuit board 300.

Alternatively, each of the timing controller 400 and the power supply unit 500 may be located in the non-display area NDA of the display panel 100, similar to the scan driver 610, the emission driver 620, and the data driver 700. In this case, the timing controller 400 may include a plurality of timing transistors, and the power supply unit 500 may include a plurality of power transistors. The plurality of timing transistors and the plurality of power transistors may be formed by a semiconductor process and formed on a semiconductor substrate SSUB (see FIG. 7). For example, the plurality of timing transistors and the plurality of power transistors may be formed as CMOSs. Each of the timing controller 400 and the power supply unit 500 may be located between the data driver 700 and the first pad unit PDA1 (see FIG. 4).

FIG. 3 is an equivalent circuit diagram of a first pixel according to one or more embodiments.

Referring to FIG. 3, a first pixel PX1 may be connected to a write scan line GWL, a bias scan line EBL, an emission control line EL, and a data line DL. In addition, the first pixel PX1 may be connected to a common voltage line VSL to which a common voltage VSS corresponding to a low potential voltage is applied, a driving voltage line VDL to which a driving voltage VDD corresponding to a high potential voltage is applied, an initialization voltage line VIL to which an initialization voltage VINT is applied, and a reference voltage line VRL to which a reference voltage VREF is applied. In this case, the common voltage VSS may be a voltage lower than the initialization voltage VINT. The driving voltage VDD may be a voltage higher than the initialization voltage VINT.

The first pixel PX1 includes a plurality of transistors T1 to T4, a light-emitting element LE, a first capacitor C1, a second capacitor C2, and a third capacitor C3.

The light-emitting element LE emits light according to a driving current flowing through a channel of a first transistor T1. An amount of light emitted from the light-emitting element LE may be proportional to the driving current. The light-emitting element LE may be connected between the first transistor T1 and the common voltage line VSL. A first electrode of the light-emitting element LE may be connected to a drain electrode of the first transistor T1, and a second electrode of the light-emitting element LE may be connected to the common voltage line VSL. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but one or more embodiments of the present disclosure is not limited thereto. For example, the light-emitting element LE may be an inorganic light-emitting element including a first electrode, a second electrode, and an inorganic semiconductor located between the first electrode and the second electrode, and in this case, the light-emitting element LE may be a micro light-emitting diode.

The first transistor T1 may be a driving transistor controlling a source-drain current (hereinafter referred to as a “driving current”) flowing between a source electrode and the drain electrode according to a voltage applied to a gate electrode thereof. The first transistor T1 includes the gate electrode connected to a first node N1, the source electrode connected to a second node N2, and the drain electrode connected to a third node N3.

A second transistor T2 may be connected between the data line DL and the first node N1. The second transistor T2 is turned on by a write scan signal of the write scan line GWL to electrically connect the data line DL and the first node N1 to each other. For this reason, a data voltage of the data line DL may be applied to one electrode of the first capacitor C1 connected to the first node. The second transistor T2 includes a gate electrode connected to the write scan line GWL, a source electrode connected to the data line DL, a drain electrode connected to the first node N1, and a body electrode connected to the driving voltage line VDL.

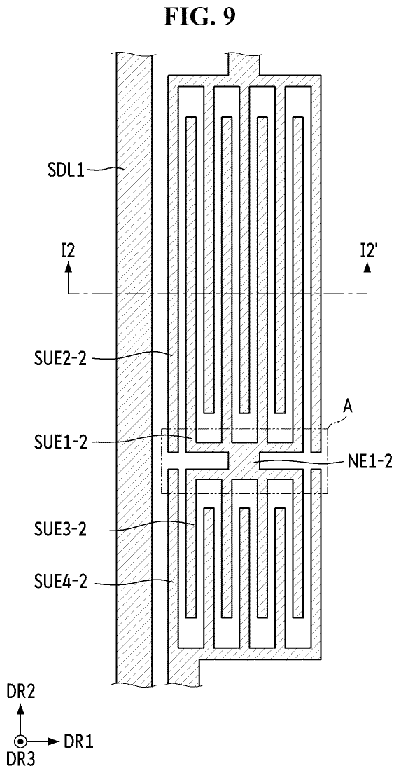

The data line may include a plurality of sub-data lines SDL1 and SDL2 (see FIGS. 9, 10, and 12) located to overlap each other along a vertical direction (e.g., the third direction). The plurality of sub-data lines SDL1 and SDL2 may be connected to each other through a via of an insulating film.

A third transistor T3 may be connected between the driving voltage line and the second node N2. The third transistor T3 may be turned on by an emission control signal of the emission control line EL to electrically connect the driving voltage line VDL and the second node N2 to each other. The third transistor T3 includes a gate electrode connected to the emission control line EL, a source electrode connected to the driving voltage line VDL, a drain electrode connected to the second node N2, and a body electrode connected to the driving voltage line VDL.

A fourth transistor T4 may be connected between the third node N3 and the initialization voltage line VIL. The fourth transistor T4 is turned on by a bias scan signal of the bias scan line EBL to connect the third node N3 and the initialization voltage line VIL to each other. The fourth transistor T4 includes a gate electrode connected to the bias scan line EBL, a drain electrode connected to the third node N3, a source electrode connected to the initialization voltage line VIL, and a body electrode connected to the initialization voltage line VIL.

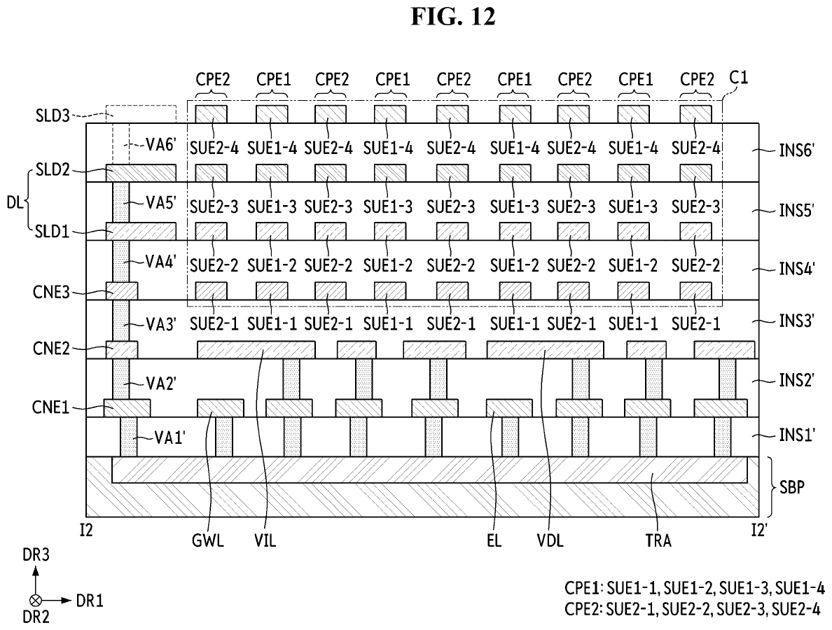

The first capacitor C1 is connected between the first node N1 and the second node N2. The first capacitor C1 may include a first capacitor electrode CPE1 (see FIG. 12) connected to the first node N1, and a second capacitor electrode CPE2 (see FIG. 12) connected to the second node N2.

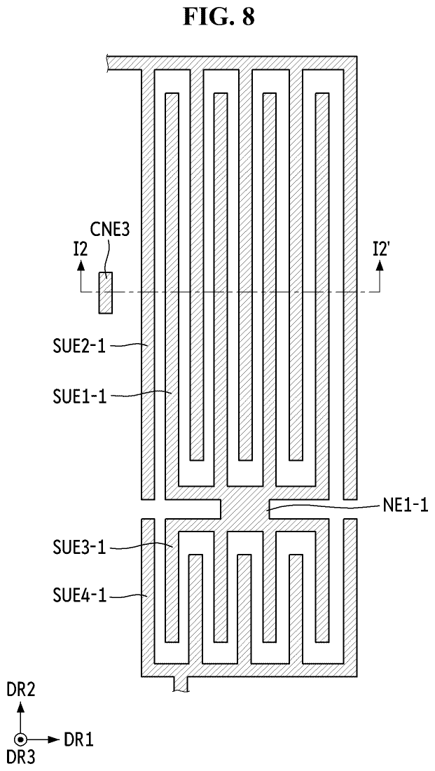

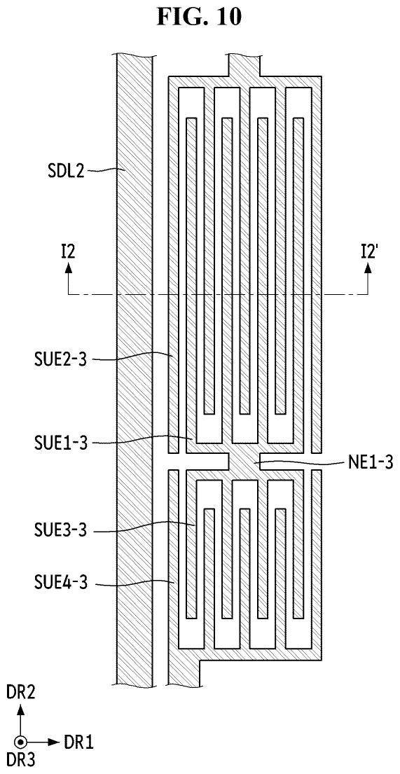

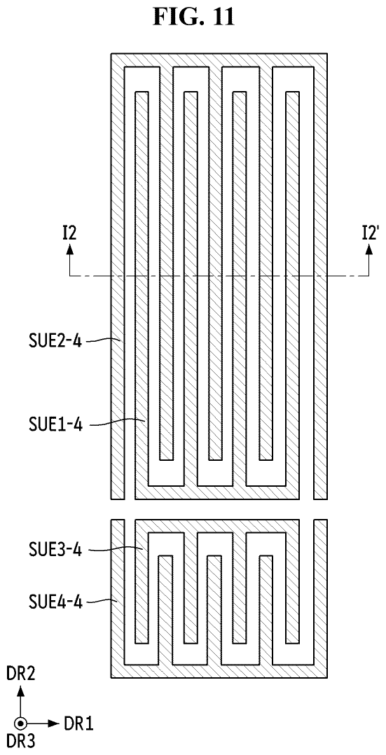

According to one or more embodiments, the first capacitor electrode CPE1 may include a first-first sub-capacitor electrode SUE1-1 (see FIGS. 8 and 12), a first-second sub-capacitor electrode SUE1-2 (see FIGS. 9 and 12), a first-third sub-capacitor electrode SUE1-3 (see FIGS. 10 and 12), and a first-fourth sub-capacitor electrode SUE1-4 (see FIGS. 11 and 12) that are located to overlap each other in the vertical direction (e.g., the third direction). The above-described first-first sub-capacitor electrode SUE1-1, first-second sub-capacitor electrode SUE1-2, first-third sub-capacitor electrode SUE1-3, and first-fourth sub-capacitor electrode SUE1-4 may be connected to the first node N1.

According to one or more embodiments, the second capacitor electrode CPE2 may include a second-first sub-capacitor electrode SUE2-1 (see FIGS. 8 and 12), a second-second sub-capacitor electrode SUE2-2 (see FIGS. 9 and 12), a second-third sub-capacitor electrode SUE2-3 (see FIGS. 10 and 12), and a second-fourth sub-capacitor electrode SUE2-4 (see FIGS. 11 and 12) that are located to overlap each other in the vertical direction (e.g., the third direction). The above-described second-first sub-capacitor electrode SUE2-1, second-second sub-capacitor electrode SUE2-2, second-third sub-capacitor electrode SUE2-3, and second-fourth sub-capacitor electrode SUE2-4 may be connected to the second node N2.

The second capacitor C2 is connected between the first node N1 and the reference voltage line VRL. The second capacitor C2 includes a third capacitor electrode connected to the first node N1 and a fourth capacitor electrode connected to the reference voltage line VRL.

According to one or more embodiments, the third capacitor electrode may include a third-first sub-capacitor electrode SUE3-1 (see FIG. 8), a third-second sub-capacitor electrode SUE3-2 (see FIG. 9), a third-third sub-capacitor electrode SUE3-3 (see FIG. 10), and a third-fourth sub-capacitor electrode SUE3-4 (see FIG. 11) that are located to overlap each other in the vertical direction (e.g., the third direction). The above-described third-first sub-capacitor electrode SUE3-1, third-second sub-capacitor electrode SUE3-2, third-third sub-capacitor electrode SUE3-3, and third-fourth sub-capacitor electrode SUE3-4 may be connected to the first node N1.

According to one or more embodiments, the fourth capacitor electrode may include a fourth-first sub-capacitor electrode SUE4-1 (see FIG. 8), a fourth-second sub-capacitor electrode SUE4-2 (see FIG. 9), a fourth-third sub-capacitor electrode SUE4-3 (see FIG. 10), and a fourth-fourth sub-capacitor electrode SUE4-4 (see FIG. 11) that are located to overlap each other in the vertical direction (e.g., the third direction). The above-described fourth-first sub-capacitor electrode SUE4-1, fourth-second sub-capacitor electrode SUE4-2, fourth-third sub-capacitor electrode SUE4-3, and fourth-fourth sub-capacitor electrode SUE4-4 may be connected to the reference voltage line VRL.

The third capacitor C3 is connected between the first node N1 and the third node N3. The third capacitor C3 includes a fifth capacitor electrode connected to the first node N1 and a sixth capacitor electrode connected to the third node N3.

Each of the first transistor T1, the second transistor T2, the third transistor T3, and the fourth transistor T4 may be a metal oxide semiconductor field effect transistor (MOSFET). For example, each of the first transistor T1, the second transistor T2, and the third transistor T3 may be a P-type MOSFET, and the fourth transistor T4 may be an N-type MOSFET.

It has been illustrated in FIG. 3 that the first pixel PX1 includes four transistors T1 to T4 and three capacitors C1, C2, and C3, but an equivalent circuit diagram of the first pixel PX1 is not limited to that illustrated in FIG. 3. For example, the numbers of transistors and capacitors of the first pixel PX1 are not limited to those illustrated in FIG. 3.

In addition, an equivalent circuit diagram of a second pixel PX2 and an equivalent circuit diagram of a third pixel PX3 may be substantially the same as the equivalent circuit diagram of the first pixel PX1 described with reference to FIG. 3. Therefore, a substantially similar description of the equivalent circuit diagram of the second pixel PX2 and the equivalent circuit diagram of the third pixel PX3 is omitted in the present disclosure.

FIG. 4 is a layout diagram illustrating an example of a display panel according to one or more embodiments.

Referring to FIG. 4, the display area DAA of the display panel 100 according to one or more embodiments includes a plurality of pixels PX arranged in a matrix form. The non-display area NDA of the display panel 100 according to one or more embodiments includes a scan driver 610, an emission driver 620, a data driver 700, a first distribution circuit 710, a second distribution circuit 720, a first pad unit PDA1, and a second pad unit PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. That is, the scan driver 610 may be located on the left side of the display area DAA, and the emission driver 620 may be located on the right side of the display area DAA. However, one or more embodiments of the present disclosure is not limited thereto, and the scan drivers 610 and the emission drivers 620 may be located on both the first and second sides of the display area DAA.

The first pad unit PDA1 may include a plurality of first pads PD1 connected to pads or bumps of the circuit board 300 through a conductive adhesive member. The first pad unit PDA1 may be located on a third side of the display area DAA. For example, the first pad unit PDA1 may be located on one side of the display area DAA in the second direction DR2.

The first pad unit PDA1 may be located outside the data driver 700 in the second direction DR2. That is, the first pad unit PDA1 may be located closer to an edge of the display panel 100 than the data driver 700 is.

The second pad unit PDA2 may include a plurality of second pads PD2 corresponding to inspection pads that inspect whether or not the display panel 100 operates normally. The plurality of second pads PD2 may be connected to a jig or a probe pin or connected to a circuit board for inspection in an inspection process. The circuit board for inspection may be a printed circuit board made of a rigid material or a flexible printed circuit board made of a flexible material.

The first distribution circuit 710 distributes data voltages applied through the first pad unit PDA1 to a plurality of data lines DL. For example, the first distribution circuit 710 may distribute data voltages applied through one first pad PD1 of the first pad unit PDA1 to P data lines DL (P is a positive integer of 2 or more), and for this reason, the number of first pads PD1 may be reduced. The first distribution circuit 710 may be located on the third side of the display area DAA of the display panel 100. For example, the first distribution circuit 710 may be located on one side of the display area DAA in the second direction DR2. That is, the first distribution circuit 710 may be located on the lower side of the display area DAA.

The second distribution circuit 720 distributes signals applied through the second pad unit PDA2 to the scan driver 610, the emission driver 620, and the data lines DL. The second pad unit PDA2 and the second distribution circuit 720 may be components for inspecting an operation of each of the pixels PX of the display area DAA. The second distribution circuit 720 may be located on a fourth side of the display area DAA of the display panel 100. For example, the second distribution circuit 720 may be located on the other side of the display area DAA in the second direction DR2. That is, the second distribution circuit 720 may be located on the upper side of the display area DAA.

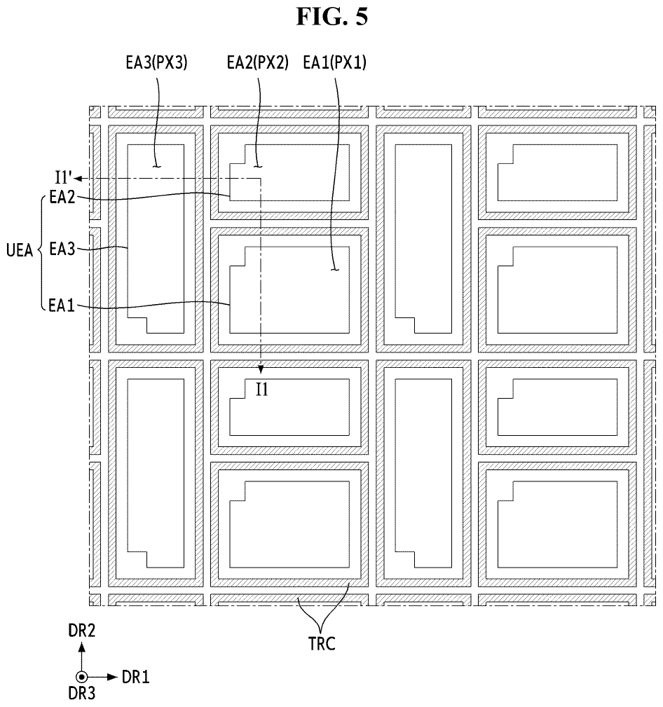

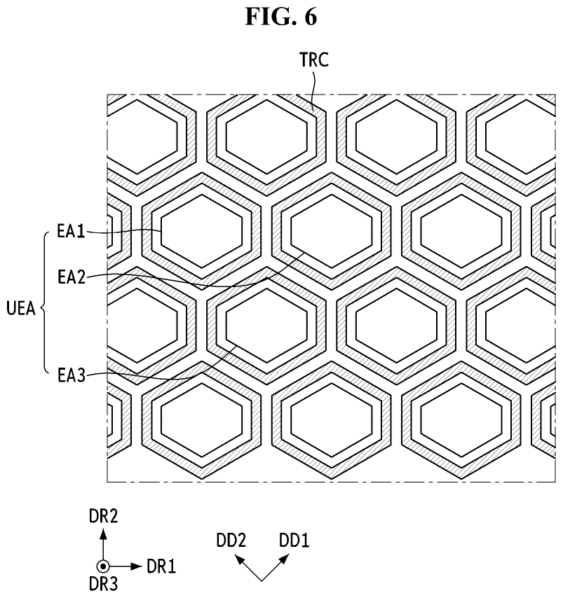

FIGS. 5 and 6 are layout diagrams illustrating embodiments of a display area of FIG. 4.

Referring to FIGS. 5 and 6, each of the plurality of unit pixels UPX includes a first emission area EA1 that is an emission area of the first pixel PX1, a second emission area EA2 that is an emission area of the second pixel PX2, and a third emission area EA3 that is an emission area of the third pixel PX3. In other words, the unit pixel UPX may include a unit emission area UEA, and this unit emission area UEA includes the above-described first emission area EA1, second emission area EA2, and third emission area EA3.

Each of the first emission area EA1, the second emission area EA2, and the third emission area EA3 may have a polygonal shape, a circular shape, an elliptical shape, or an irregular shape in plan view.

A maximum length of the third emission area EA3 in the first direction DR1 may be less than a maximum length of the first emission area EA1 in the first direction DR1 and a maximum length of the second emission area EA2 in the first direction DR1. The maximum length of the first emission area EA1 in the first direction DR1 and the maximum length of the second emission area EA2 in the first direction DR1 may be substantially the same as each other.

A maximum length of the third emission area EA3 in the second direction DR2 may be greater than a maximum length of the first emission area EA1 in the second direction DR2 and a maximum length of the second emission area EA2 in the second direction DR2. The maximum length of the first emission area EA1 in the second direction DR2 may be greater than the maximum length of the second emission area EA2 in the second direction DR2. The maximum length of the first emission area EA1 in the second direction DR2 may be less than the maximum length of the third emission area EA3 in the second direction DR2.

Each of the first emission area EA1, the second emission area EA2, and the third emission area EA3 may have a hexagonal shape including six straight lines, in plan view, as illustrated in FIGS. 5 and 6, but one or more embodiments of the present disclosure is not limited thereto. Each of the first emission area EA1, the second emission area EA2, and the third emission area EA3 may have polygonal shapes other than the hexagonal shape, a circular shape, an elliptical shape, or an irregular shape in plan view.

As illustrated in FIG. 5, in each of the plurality of unit pixels UPX, the second emission area EA2 and the third emission area EA3 may neighbor to each other in the first direction DR1. In addition, the first emission area EA1 and the third emission area EA3 may neighbor to each other in the first direction DR1. In addition, the first emission area EA1 and the second emission area EA2 may neighbor to each other in the second direction DR2. An area of the first emission area EA1, an area of the second emission area EA2, and an area of the third emission area EA3 may be different from each other.

Alternatively, as illustrated in FIG. 6, the first emission area EA1 and the second emission area EA2 may neighbor to each other in the first direction DR1, but the second emission area EA2 and the third emission area EA3 may neighbor to each other in a first diagonal direction DD1, and the first emission area EA1 and the third emission area EA3 may neighbor to each other in a second diagonal direction DD2. The first diagonal direction DD1 is a direction between the first direction DR1 and the second direction DR2 and may refer to a direction inclined by 45° with respect to the first direction DR1 and the second direction DR2, and the second diagonal direction DD2 may be a direction orthogonal to the first diagonal direction DD1.

The first emission area EA1 may emit light of a first color, the second emission area EA2 may emit light of a second color, and the third emission area EA3 may emit light of a third color. Here, the light of the first color may be light of a blue wavelength band, the light of the second color may be light of a green wavelength band, and the light of the third color may be light of a red wavelength band. For example, the blue wavelength band may indicate that a main peak wavelength of the light is included in a wavelength band of approximately 370 nm to approximately 460 nm, the green wavelength band may indicate that a main peak wavelength of the light is included in a wavelength band of approximately 480 nm to approximately 560 nm, and the red wavelength band may indicate that a main peak wavelength of the light is included in a wavelength band of approximately 600 nm and approximately 750 nm.

It has been illustrated in FIGS. 5 and 6 that each of the plurality of unit pixels UPX includes three emission areas EA1, EA2, and EA3, but one or more embodiments of the present disclosure is not limited thereto. That is, each of the plurality of unit pixels UPX may also include four emission areas.

In addition, an arrangement of the emission areas of the plurality of unit pixels UPX is not limited to those illustrated in FIGS. 5 and 6. For example, the emission areas of the plurality of unit pixels UPX may be located in a stripe structure in which the emission areas are arranged in the first direction DR1, a PenTile® structure in which the emission areas have a diamond arrangement, or a hexagonal structure in which emission areas having a hexagonal shape in plan view are arranged as illustrated in FIG. 6 (PenTile® being a registered trademark of Samsung Display Co., Ltd., Republic of Korea).

FIG. 7 is a cross-sectional view illustrating an example of the display panel taken along line 11-11′ of FIG. 5.

Referring to FIG. 7, the display panel 100 includes a semiconductor backplane SBP, a light-emitting element backplane EBP, a display element layer EML, an encapsulation layer TFE, an optical layer OPL, a cover layer CVL, and a polarizing plate POL.

The semiconductor backplane SBP may include a semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to fourth transistors T1 to T4 described with reference to FIG. 3.

The semiconductor substrate SSUB may be a silicon substrate, a germanium substrate, or a silicon-germanium substrate. The semiconductor substrate SSUB may be a substrate doped with first-type impurities. A plurality of well regions WA may be located in an upper surface of the semiconductor substrate SSUB. The plurality of well regions WA may be regions doped with second-type impurities. The second-type impurities may be different from the first-type impurities described above. For example, when the first-type impurities are p-type impurities, the second-type impurities may be n-type impurities. Alternatively, when the first-type impurities are n-type impurities, the second-type impurities may be p-type impurities.

Each of the plurality of well regions WA includes a source region SA corresponding to a source electrode of the pixel transistor PTR, a drain region DA corresponding to a drain electrode of the pixel transistor PTR, and a channel region CH located between the source region SA and the drain region DA.

A bottom insulating film BINS may be located between a gate electrode GE and the well region WA. Side surface insulating films SINS may be located on side surfaces of the gate electrode GE. The side surface insulating films SINS may be located on the bottom insulating film BINS.

Each of the source region SA and the drain region DA may be a region doped with the first-type impurities. The gate electrode GE of the pixel transistor PTR may overlap the well region WA in the third direction DR3. The channel region CH may overlap the gate electrode GE in the third direction DR3. The source region SA may be located on one side of the gate electrode GE, and the drain region SA may be located on the other side of the gate electrode GE.

Each of the plurality of well regions WA further includes a first low-concentration impurity region LDD1 located between the channel region CH and the source region SA and a second low-concentration impurity region LDD2 located between the channel region CH and the drain region DA. The first low-concentration impurity region LDD1 may be a region having a lower impurity concentration than the source region SA due to the bottom insulating film BINS. The second low-concentration impurity region LDD2 may be a region having a lower impurity concentration than the drain region DA due to the bottom insulating film BINS. A distance between the source region SA and the drain region DA may increase by the first low-concentration impurity region LDD1 and the second low-concentration impurity region LDD2. Therefore, a length of the channel region CH of each of the pixel transistors PTR may increase, and thus, punch-through and hot carrier phenomena caused by a short channel may be reduced or prevented.

A first semiconductor insulating film SINS1 may be located on the semiconductor substrate SSUB. The first semiconductor insulating film SINS1 may be formed as a silicon carbonitride (SiCN) or silicon oxide (SiOₓ)-based inorganic film, but one or more embodiments of the present disclosure is not limited thereto.

A second semiconductor insulating film SINS2 may be located on the first semiconductor insulating film SINS1. The second semiconductor insulating film SINS2 may be formed as a silicon oxide (SiOₓ)-based inorganic film, but one or more embodiments of the present disclosure is not limited thereto.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through a hole penetrating through the first semiconductor insulating film SINS1 and the second semiconductor insulating film INS2. Each of the plurality of contact terminals CTE may be made of any one of copper (Cu), aluminum (AI), tungsten (W), molybdenum (Mo), chromium (Cr), gold (Au), titanium (Ti), nickel (Ni), or neodymium (Nd), or alloys thereof.

A third semiconductor insulating film SINS3 may be located on side surfaces of each of the plurality of contact terminals CTE. An upper surface of each of the plurality of contact terminals CTE may be exposed without being covered by the third semiconductor insulating film SINS3. The third semiconductor insulating film SINS3 may be formed as a silicon oxide (SiOₓ)-based inorganic film, but one or more embodiments of the present disclosure is not limited thereto.

The semiconductor substrate SSUB may be replaced with a glass substrate or a polymer resin substrate, such as a polyimide substrate. In this case, thin film transistors may be located on the glass substrate or the polymer resin substrate. The glass substrate may be a rigid substrate that is not bent, and the polymer resin substrate may be a flexible substrate that may be bent or curved.

The light-emitting element backplane EBP includes a plurality of conductive layers ML1 to ML8, a plurality of vias VA1 to VA9, and a plurality of insulating films INS1 to INS9. In addition, the light-emitting element backplane EBP includes a plurality of insulating films INS1 to INS9 located between first to eighth conductive layers ML1 to ML8.

The first to eighth conductive layers ML1 to ML8 serve to implement a circuit of the first pixel PX1 illustrated in FIG. 3 by connecting the plurality of contact terminals CTE exposed from the semiconductor backplane SBP to each other. For example, only the first to fourth transistors T1 to T4 are formed in the semiconductor backplane SBP, and the connection between the first to fourth transistors T1 to T4 and the formation of the first capacitor C1, the second capacitor C2, and the third capacitor C3 are performed through the first to eighth conductive layers ML1 to ML8. In addition, the connection between a drain region corresponding to the drain electrode of the fourth transistor T4, a source region corresponding to the source electrode of the fifth transistor T5, and the first electrode of the light-emitting element LE is also performed through the first to eighth conductive layers ML1 to ML8.

A first insulating film INS1 may be located on the semiconductor backplane SBP. Each of first vias VA1 may penetrate through the first film INS1 to be connected to the contact terminal CTE exposed from the semiconductor backplane SBP. Each of the first conductive layers ML1 may be located on the first insulating film INS1, and may be connected to the first via VA1.

A second insulating film INS2 may be located on the first insulating film INS1 and the first conductive layers ML1. Each of second vias VA2 may penetrate through the second insulating film INS2 to be connected to the exposed first conductive layer ML1. Each of the second conductive layers ML2 may be located on the second insulating film INS2, and may be connected to the second via VA2.

A third insulating film INS3 may be located on the second insulating film INS2 and the second conductive layers ML2. Each of third vias VA3 may penetrate through the third insulating film INS3 to be connected to the exposed second conductive layer ML2. Each of the third conductive layers ML3 may be located on the third insulating film INS3, and may be connected to the third via VA3.

A fourth insulating film INS4 may be located on the third insulating film INS3 and the third conductive layer ML3. Each of fourth vias VA4 may penetrate through the fourth insulating film INS4 to be connected to the exposed third conductive layer ML3. Each of the fourth conductive layers ML4 may be located on the fourth insulating film INS4, and may be connected to the fourth via VA4.

A fifth insulating film INS4 may be located on the fourth insulating film INS4 and the fourth conductive layers ML4. Each of fifth vias VA5 may penetrate through the fifth film INS5 to be connected to the exposed fourth conductive layer ML4. Each of the fifth conductive layers ML5 may be located on the fifth insulating film INS5, and may be connected to the fifth via VA5.

A sixth insulating film INS6 may be located on the fifth insulating film INS5 and the fifth conductive layer ML5. Each of sixth vias VA6 may penetrate through the sixth insulating film INS6 to be connected to the exposed fifth conductive layer ML5. Each of the sixth conductive layers ML6 may be located on the sixth insulating film INS6, and may be connected to the sixth via VA6.

A seventh insulating film INS7 may be located on the sixth insulating film INS6 and the sixth conductive layer ML6. Each of seventh vias VA7 may penetrate through the seventh insulating film INS7 to be connected to the exposed sixth conductive layer ML6. Each of the seventh conductive layers ML7 may be located on the seventh insulating film INS7, and may be connected to the seventh via VA7.

An eighth insulating film INS8 may be located on the seventh insulating film INS7 and the seventh conductive layer ML7. Each of eighth vias VA8 may penetrate through the eighth insulating film INS8 to be connected to the exposed seventh conductive layer ML7. Each of the eighth conductive layers ML8 may be located on the eighth insulating film INS8, and may be connected to the eighth via VA8.

The first to eighth conductive layers ML1 to ML8 and the first to eighth vias VA1 to VA8 may be made of substantially the same material. Each of the first to eighth conductive layers ML1 to ML8 and the first to eighth vias VA1 to VA8 may be made of any one of copper (Cu), aluminum (Al), tungsten (W), molybdenum (Mo), chromium (Cr), gold (Au), titanium (Ti), nickel (Ni), or neodymium (Nd), or alloys thereof. The first to eighth vias VA1 to VA8 may be made of substantially the same material. The first to eighth insulating films INS1 to INS8 may be formed as silicon oxide (SiOₓ)-based inorganic films, but one or more embodiments of the present disclosure is not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via VA1, a thickness of the second via VA2, a thickness of the third via VA3, a thickness of the fourth via VA4, a thickness of the fifth via VA5, and a thickness of the sixth via VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same as each other. For example, the thickness of the first conductive layer ML1 may be approximately 1360 Å, each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be approximately 1440 Å, and each of the thickness of the first via VA1, the thickness of the second via VA2, the thickness of the third via VA3, the thickness of the fourth via VA4, the thickness of the fifth via VA5, and the thickness of the sixth via VA6 may be approximately 1150 Å.

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. Each of the thickness of the seventh conductive layer ML7 and the eighth conductive layer ML8 may be greater than each of a thickness of the seventh via VA7 and a thickness of the eighth via VA8. Each of the thickness of the seventh via VA7 and the thickness of the eighth via VA8 may be greater than each of the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same as each other. For example, each of the thickness of the seventh conductive layer ML7 and the thickness of the eighth conductive layer ML8 may be approximately 9000 Å. Each of the thickness of the seventh via VA7 and the thickness of the eighth via VA8 may be approximately 6000 Å.

A ninth insulating film INS9 may be located on the eighth insulating film INS8 and the eighth conductive layer ML8. The ninth insulating film INS9 may be formed as a silicon oxide (SiOₓ)-based inorganic film, but one or more embodiments of the present disclosure is not limited thereto.

Each of ninth vias VA9 may penetrate through the ninth insulating film INS9 to be connected to the exposed eighth conductive layer ML8. Each of the ninth vias VA9 may be made of any one of copper (Cu), aluminum (AI), tungsten (W), molybdenum (Mo), chromium (Cr), gold (Au), titanium (Ti), nickel (Ni), or neodymium (Nd), or alloys thereof. A thickness of the ninth via VA9 may be approximately 16500 Å.

The display element layer EML may be located on the light-emitting element backplane EBP. The display element layer EML may include a reflective electrode layer RL, tenth and eleventh insulating films INS10 and INS11, tenth vias VA10, light-emitting elements LE each including a first electrode AND, a light-emitting stack ES, and a second electrode CAT, a pixel-defining film PDL, and a plurality of trenches TRC.

The reflective electrode layer RL may be located on the ninth insulating film INS9. The reflective electrode layer RL may include one or more reflective electrodes RL1, RL2, RL3, and RL4. For example, the reflective electrode layer RL may include first to fourth reflective electrodes RL1, RL2, RL3, and RL4 as illustrated in FIG. 7.

Each of the first reflective electrodes RL1 may be located on the ninth insulating film INS9, and may be connected to the ninth via VA9. Each of the first reflective electrodes RL1 may be made of any one of copper (Cu), aluminum (Al), tungsten (W), molybdenum (Mo), chromium (Cr), gold (Au), titanium (Ti), nickel (Ni), or neodymium (Nd), or alloys thereof. For example, each of the first reflective electrodes RL1 may include titanium nitride (TiN).

Each of the second reflective electrodes RL2 may be located on the first reflective electrode RL1. Each of the second reflective electrodes RL2 may be made of any one of copper (Cu), aluminum (AI), tungsten (W), molybdenum (Mo), chromium (Cr), gold (Au), titanium (Ti), nickel (Ni), or neodymium (Nd), or alloys thereof. For example, each of the second reflective electrodes RL2 may include aluminum (Al).

Each of the third reflective electrodes RL3 may be located on the second reflective electrode RL2. Each of the third reflective electrodes RL3 may be made of any one of copper (Cu), aluminum (AI), tungsten (W), molybdenum (Mo), chromium (Cr), gold (Au), titanium (Ti), nickel (Ni), or neodymium (Nd), or alloys thereof. For example, each of the third reflective electrodes RL3 may include titanium nitride (TiN).

Each of the fourth reflective electrodes RL4 may be located on the third reflective electrode RL3. Each of the fourth reflective electrodes RL4 may be made of any one of copper (Cu), aluminum (AI), tungsten (W), molybdenum (Mo), chromium (Cr), gold (Au), titanium (Ti), nickel (Ni), or neodymium (Nd), or alloys thereof. For example, each of the fourth reflective electrodes RL4 may include titanium (Ti).

Because the second reflective electrodes RL2 are electrodes substantially reflecting light from the light-emitting elements LE, a thickness of the second reflective electrode RL2 may be greater than a thickness of the first reflective electrode RL1, a thickness of the third reflective electrode RL3, and a thickness of the fourth reflective electrode RL4. For example, each of the thickness of the first reflective electrode RL1, the third reflective electrode RL3, and the fourth reflective electrode RL4 may be approximately 100 Å, and the thickness of the second reflective electrode RL2 may be approximately 850 Å.

The tenth insulating film INS10 may be located on the ninth insulating film INS9. The tenth insulating film INS10 may be located between the reflective electrode layers RL adjacent to each other in a horizontal direction. The tenth insulating film INS10 may be located on the reflective electrode layer RL in the third pixel PX3. The tenth insulating film INS10 may be formed as a silicon oxide (SiOₓ)-based inorganic film, but one or more embodiments of the present disclosure is not limited thereto.

The eleventh insulating film INS11 may be located on the tenth insulating film INS10 and the reflective electrode layer RL. The eleventh insulating film INS11 may be formed as a silicon oxide (SiOₓ)-based inorganic film, but one or more embodiments of the present disclosure is not limited thereto. The tenth insulating film INS10 and the eleventh insulating film INS11 may be optical auxiliary layers through which light reflected by the reflective electrode layer RL among light emitted from the light-emitting elements LE passes.

To adjust a resonance distance of the light emitted from the light-emitting elements LE in at least one of the first pixel PX1, the second pixel PX2, and the third pixel PX3, the tenth insulating film INS10 and the eleventh insulating film INS11 may not be located below the first electrode AND of the first pixel PX1. The first electrode AND of the first pixel PX1 may be directly located on the reflective electrode layer RL. The eleventh insulating film INS11 may be located below the first electrode AND of the second pixel PX2. The tenth insulating film INS10 and the eleventh insulating film INS11 may be located below the first electrode AND of the third pixel PX3.

In summary, a respective distance between the first electrode AND and the reflective electrode layer RL may be different in each of the first pixel PX1, the second pixel PX2, and the third pixel PX3. That is, to adjust a distance from the reflective electrode layer RL to the second electrode CAT according to a main wavelength of light emitted from each of the first pixel PX1, the second pixel PX2, and third the pixel PX3, the presence or absence of the tenth insulating film INS10 and the eleventh insulating film INS11 may be set in each of the first pixel PX1, the second pixel PX2, and the third pixel PX3. For example, it has been illustrated in FIG. 7 that a distance between the first electrode AND and the reflective electrode layer RL in the third pixel PX3 is greater than a distance between the first electrode AND and the reflective electrode layer RL in the second pixel PX2 and is greater than a distance between the first electrode AND and the reflective electrode layer RL in the first pixel PX1. The distance between the first electrode AND and the reflective electrode layer RL in the second pixel PX2 is greater than the distance between the first electrode AND and the reflective electrode layer RL in the first pixel PX1. However, one or more embodiments of the present disclosure is not limited thereto.

In addition, the tenth insulating film INS10 and the eleventh insulating film INS11 have been illustrated in one or more embodiments of the present disclosure, but a twelfth insulating film located below the first electrode AND of the first pixel PX1 may be added. In this case, the eleventh insulating film INS11 and the twelfth insulating film may be located below the first electrode AND of the second pixel PX2, and the tenth insulating film INS10, the eleventh insulating film INS11, and the twelfth insulating film may be located below the first electrode AND of the third pixel PX3.

Each of the tenth vias VA10 may penetrate through the tenth insulating film INS10 and/or the eleventh insulating film INS11 in the second pixel PX2 and the third pixel PX3 to be connected to the exposed fourth reflective electrode RL4. Each of the tenth vias VA10 may be made of any one of copper (Cu), aluminum (AI), tungsten (W), molybdenum (Mo), chromium (Cr), gold (Au), titanium (Ti), nickel (Ni), or neodymium (Nd), or alloys thereof. A thickness of the tenth via VA10 in the second pixel PX2 may be less than a thickness of the tenth via VA10 in the third pixel PX3.

The first electrode AND of each of the light-emitting elements LE may be located on the tenth insulating film INS10, and may be connected to the tenth via VA10. The first electrode AND of each of the light-emitting elements LE may be connected to the drain region DA or the source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be made of any one of copper (Cu), aluminum (AI), tungsten (W), molybdenum (Mo), chromium (Cr), gold (Au), titanium (Ti), nickel (Ni), or neodymium (Nd), or alloys thereof. For example, the first electrode AND of each of the light-emitting elements LE may be made of titanium nitride (TiN).

The pixel-defining film PDL may be located on a partial area of the first electrode AND of each of the light-emitting elements LE. The pixel-defining film PDL may cover an edge of the first electrode AND of each of the light-emitting elements LE. The pixel-defining film PDL serves to partition the first emission areas EA1, the second emission areas EA2, and the third emission areas EA3.

The first emission area EA1 may be defined as an area where the first electrode AND, the light-emitting stack ES, and the second electrode CAT are sequentially stacked in the first pixel PX1 to emit light. The second emission area EA2 may be defined as an area where the first electrode AND, the light-emitting stack ES, and the second electrode CAT are sequentially stacked in the second pixel PX2 to emit light. The third emission area EA3 may be defined as an area where the first electrode AND, the light-emitting stack ES, and the second electrode CAT are sequentially stacked in the third pixel PX3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed as silicon oxide (SiOₓ)-based inorganic films, but one or more embodiments of the present disclosure is not limited thereto. Each of a thickness of the first pixel-defining film PDL1, a thickness of the second pixel-defining film PDL2, and a thickness of the third pixel-defining film PDL3 may be approximately 500 Å.

When the first pixel-defining film PDL1, the second pixel-defining film PDL2, and the third pixel-defining film PDL3 are formed as one pixel-defining film, a height of the one pixel-defining film increases, such that a first encapsulation inorganic film TFE1 may be disconnected due to step coverage. The step coverage refers to a ratio of a degree at which a thin film is coated on an inclined portion to a degree at which a thin film is coated on a flat portion. The lower the step coverage, the more likely it is that the thin film will be disconnected at the inclined portion.

Therefore, to reduce or prevent the likelihood of the first encapsulation inorganic film TFE1 being disconnected due to the step coverage, the first pixel-defining film PDL1, the second pixel-defining film PDL2, and the third pixel-defining film PDL3 may have a cross-sectional structure with a step having a staircase shape. For example, a width of the first pixel-defining film PDL1 may be greater than a width of the second pixel-defining film PDL2 and may be greater than a width of the third pixel-defining film PDL3. The width of the second pixel-defining film PDL2 may be greater than the width of the third pixel-defining film PDL3. The width of the first pixel-defining film PDL1 refers to a length of the first pixel-defining film PDL1 in the horizontal direction defined by the first direction DR1 and the second direction DR2.

Each of the plurality of trenches TRC may penetrate through the first pixel-defining film PDL1, the second pixel-defining film PDL2, and the third pixel-defining film PDL3. In addition, each of the plurality of trenches TRC may penetrate through the eleventh insulating film INS11. In each of the plurality of trenches TRC, the tenth insulating film INS10 may have a shape in which a portion thereof is trenched.

At least one trench TRC may be located between the pixels PX1, PX2, and PX3 neighboring to each other. It has been illustrated in FIG. 7 that two trenches TRC are located between the pixels PX1, PX2, and PX3 neighboring to each other, but one or more embodiments of the present disclosure is not limited thereto.

The light-emitting stack ES may include a plurality of stack layers. It has been illustrated in FIG. 7 that the light-emitting stack ES has a three-tandem structure including a first stack layer IL1, a second stack layer IL2, and a third stack layer IL3, but one or more embodiments of the present disclosure is not limited thereto. For example, the light-emitting stack ES may have a two-tandem structure including two intermediate layers.

In the three-tandem structure, the light-emitting stack ES may have a tandem structure including a plurality of stack layers IL1, IL2, and IL3 emitting different light. For example, the light-emitting stack ES may include a first stack layer IL1 for emitting light of a first color, a second stack layer IL2 for emitting light of a third color, and a third stack layer IL3 for emitting light of a second color. The first stack layer IL1, the second stack layer IL2, and the third stack layer IL3 may be sequentially stacked.

The first stack layer IL1 may have a structure in which a first hole-transporting layer, a first organic light-emitting layer emitting the light of the first color, and a first electron-transporting layer are sequentially stacked. The second stack layer IL2 may have a structure in which a second hole-transporting layer, a second organic light-emitting layer emitting the light of the third color, and a second electron-transporting layer are sequentially stacked. The third stack layer IL3 may have a structure in which a third hole-transporting layer, a third organic light-emitting layer emitting the light of the second color, and a third electron-transporting layer are sequentially stacked.

A first charge generation layer for supplying charges to the second stack layer IL2 and supplying electrons to the first stack layer IL1 may be located between the first stack layer IL1 and the second stack layer IL2. The first charge generation layer may include an N-type charge generation layer supplying electrons to the first stack layer IL1 and a P-type charge generation layer supplying holes to the second stack layer IL2. The N-type charge generation layer may include a dopant of a metal material.

A second charge generation layer for supplying charges to the third stack layer IL3 and supplying electrons to the second stack layer IL2 may be located between the second stack layer IL2 and the third stack layer IL3. The second charge generation layer may include an N-type charge generation layer supplying electrons to the second stack layer IL2 and a P-type charge generation layer supplying holes to the third stack layer IL3.

The first stack layer IL1 may be located on the first electrodes AND and the pixel-defining film PDL, and may be located on a bottom surface of each of the trenches TRC. Due to the trenches TRC, the first stack layer IL1 may be disconnected between the pixels PX1, PX2, and PX3 neighboring to each other. The second stack layer IL2 may be located on the first stack layer IL1. Due to the trenches TRC, the second stack layer IL2 may be disconnected between the pixels PX1, PX2, and PX3 neighboring to each other. A cavity ESS or an empty space may be located between the first stack layer IL1 and the second stack layer IL2. The third stack layer IL3 may be located on the second stack layer IL2. The third stack layer IL3 may not be disconnected by the trenches TRC, and may be located to cover the second stack layer IL2 in each of the trenches TRC. That is, in the three-tandem structure, each of the plurality of trenches TRC may be a structure for disconnecting the first and second stack layers IL1 and IL2, the first charge generation layer, and the second charge generation layer of the display element layer EML between the pixels PX1, PX2, and PX3 neighboring to each other. In addition, in the two-tandem structure, each of the plurality of trenches TRC may be a structure for disconnecting a charge generation layer located between a lower intermediate layer and an upper intermediate layer and the lower intermediate layer.

To stably disconnect the first and second stack layers IL1 and IL2 of the display element layer EML between the pixels PX1, PX2, and PX3 neighboring to each other, a height of each of the plurality of trenches TRC may be greater than a height of the pixel-defining film PDL. The height of each of the plurality of trenches TRC refers to a length of each of the plurality of trenches TRC in the third direction DR3. The height of the pixel-defining film PDL refers to a length of the pixel-defining film PDL in the third direction DR3. To disconnect the first and second stack layers IL1 and IL2 of the display element layer EMTL between the pixels PX1, PX2, and PX3 neighboring to each other, other structures may exist instead of the trenches TRC. For example, instead of the trenches TRC, partition walls having a reverse tapered shape may be located on the pixel-defining film PDL.

The number of stack layers IL1, IL2, and IL3 emitting the different light is not limited to that illustrated in FIG. 7. For example, the light-emitting stack ES may include two intermediate layers. In this case, any one of the two intermediate layers may be substantially the same as the first stack layer IL1, and the other of the two intermediate layers may include a second hole-transporting layer, a second organic light-emitting layer, a third organic light-emitting layer, and a second electron-transporting layer. In this case, a charge generation layer for supplying electrons to any one intermediate layer and supplying charges to the other intermediate layer may be located between the two intermediate layers.

It has been illustrated in FIG. 7 that the first to third stack layers IL1, IL2, and IL3 are all located in the first emission area EA1, the second emission area EA2, and the third emission area EA3, but one or more embodiments of the present disclosure is not limited thereto. For example, the first stack layer IL1 may be located in the first emission area EA1, and may not be located in the second emission area EA2 and the third emission area EA3. In addition, the second stack layer IL2 may be located in the second emission area EA2, and may not be located in the first emission area EA1 and the third emission area EA3. In addition, the third stack layer IL3 may be located in the third emission area EA3, and may not be located on the first emission area EA1 and the second emission area EA2. In this case, first to third color filters CF1, CF2, and CF3 of the optical layer OPL may be omitted.

The second electrode CAT may be located on the third stack layer IL3. The second electrode CAT may be located on the third stack layer IL3 in each of the plurality of trenches TRC. The second electrode CAT may be made of a transparent conductive material (TCO), such as indium tin oxide (ITO) or indium zinc oxide (IZO) capable of transmitting light therethrough or a semi-transmissive conductive material, such as magnesium (Mg), silver (Ag), or an alloy of magnesium (Mg) and silver (Ag). When the second electrode CAT is made of the semi-transmissive conductive material, light emission efficiency of each of the first to third pixels PX1, PX2, and PX3 may be increased by a micro cavity.

The encapsulation layer TFE may be located on the display element layer EML. The encapsulation layer TFE may include at least one inorganic film TFE1 or TFE2 to reduce or prevent permeation of oxygen or moisture into the display element layer EML. For example, the encapsulation layer TFE may include a first encapsulation inorganic film TFE1 and a second encapsulation inorganic film TFE2.

The first encapsulation inorganic film TFE1 may be located on the second electrode CAT. The first encapsulation inorganic film TFE1 may be formed as multiple films in which one or more inorganic films of a silicon nitride (SiNx) layer, a silicon oxynitride (SiON) layer, and a silicon oxide (SiOₓ) layer are alternately stacked. The first encapsulation inorganic film TFE1 may be formed by a chemical vapor deposition (CVD) process.

The second encapsulation inorganic film TFE2 may be located on the first encapsulation inorganic film TFE1. The second encapsulation inorganic film TFE2 may be formed as a titanium oxide (TiOₓ) layer or an aluminum oxide (AlOₓ) layer, but one or more embodiments of the present disclosure is not limited thereto. The second encapsulation inorganic film TFE2 may be formed by an atomic layer deposition (ALD) process. A thickness of the second encapsulation inorganic film TFE2 may be less than a thickness of the first encapsulation inorganic film TFE1.

An organic film APL may be a layer for increasing interfacial adhesive strength between the encapsulation layer TFE and the optical layer OPL. The organic film APL may be an organic film made of an acrylic resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the organic film APL.

The first color filter CF1 may overlap the first emission area EA1 of the first pixel PX1. The first color filter CF1 may transmit the light of the first color, that is, light of a blue wavelength band, therethrough. The blue wavelength band may be approximately 370 nm to approximately 460 nm. Therefore, the first color filter CF1 may transmit the light of the first color among light emitted from the first emission area EA1 therethrough.

The second color filter CF2 may overlap the second emission area EA2 of the second pixel PX2. The second color filter CF2 may transmit the light of the second color, that is, light of a green wavelength band, therethrough. The green wavelength band may be approximately 480 nm to approximately 560 nm. Therefore, the second color filter CF2 may transmit the light of the second color among light emitted from the second emission area EA2 therethrough.

The third color filter CF3 may overlap the third emission area EA3 of the third pixel PX3. The third color filter CF3 may transmit the light of the third color, that is, light of a red wavelength band, therethrough. The blue wavelength band may be approximately 600 nm to approximately 750 nm. Therefore, the third color filter CF3 may transmit the light of the third color among light emitted from the third emission area EA3 therethrough.

Each of the plurality of lenses LNS may be located on each of the first color filter CF1, the second color filter CF2, and the third color filter CF3. Each of the plurality of lenses LNS may be a structure for increasing a ratio of light directed to a front surface of the display device 10. Each of the plurality of lenses LNS may have a cross-sectional shape convex in an upward direction.

The filling layer FIL may be located on the plurality of lenses LNS. The filling layer FIL may have a refractive index (e.g., predetermined refractive index) so that light travels in the third direction DR3 at an interface between the plurality of lenses LNS and the filling layer FIL. In addition, the filling layer FIL may be a planarizing layer. The filling layer FIL may be an organic film made of an acrylic resin, an epoxy resin, a phenolic resin, a polyamide resin, a polyimide resin, or the like.

The cover layer CVL may be located on the filling layer FIL. The cover layer CVL may be a glass substrate or a polymer resin, such as a resin. When the cover layer CVL is the glass substrate, the cover layer CVL may be attached onto the filling layer FIL. In this case, the filling layer FIL may serve to adhere the cover layer CVL. When the cover layer CVL is the glass substrate, the cover layer CVL may serve as an encapsulation substrate. When the cover layer CVL is the polymer resin, such as the resin, the cover layer CVL may be directly applied onto the filling layer FIL.

The polarizing plate POL may be located on one surface of the cover layer CVL. The polarizing plate POL may be a structure for reducing or preventing deterioration in visibility due to external light reflection. The polarizing plate POL may include a linear polarizing plate and a phase retardation film. For example, the phase retardation film may be a λ/4 plate (quarter-wave plate), but one or more embodiments of the present disclosure is not limited thereto. However, when visibility due to external light reflection is sufficiently improved by the first to third color filters CF1, CF2, and CF3, the polarizing plate POL may be omitted.

FIG. 8 is a plan view of a first-first sub-capacitor electrode SUE1-1 of a first capacitor electrode CPE1, a second-first sub-capacitor electrode SUE2-1 of a second capacitor electrode CPE2, a third-first sub-capacitor electrode SUE3-1 of a third capacitor electrode, a fourth-first sub-capacitor electrode SUE4-1 of a fourth capacitor electrode, and a third connection electrode CNE3. FIG. 9 is a plan view of a first-second sub-capacitor electrode SUE1-2 of the first capacitor electrode CPE1, a second-second sub-capacitor electrode SUE2-2 of the second capacitor electrode CPE2, a third-second sub-capacitor electrode SUE3-2 of the third capacitor electrode, a fourth-second sub-capacitor electrode SUE4-2 of the fourth capacitor electrode, and a first sub-data line SDL1. FIG. 10 is a plan view of a first-third sub-capacitor electrode SUE1-3 of the first capacitor electrode CPE1, a second-third sub-capacitor electrode SUE2-3 of the second capacitor electrode CPE2, a third-third sub-capacitor electrode SUE3-3 of the third capacitor electrode, a fourth-third sub-capacitor electrode SUE4-3 of the fourth capacitor electrode, and a second sub-data line SDL2. FIG. 11 is a plan view of a first-fourth sub-capacitor electrode SUE1-4 of the first capacitor electrode CPE1, a second-fourth sub-capacitor electrode SUE2-4 of the second capacitor electrode CPE2, a third-fourth sub-capacitor electrode SUE3-4 of the third capacitor electrode, and a fourth-fourth sub-capacitor electrode SUE4-4 of the fourth capacitor electrode. FIG. 12 is a cross-sectional view illustrating an example of the display panel taken along line 12-12′ of FIGS. 8 to 11.

As illustrated in FIGS. 8 to 10, the first node N1 may include a plurality of node electrodes NE1-1, NE1-2, and NE1-3 located adjacent to each other in the vertical direction (e.g., in the third direction DR3). For example, the first node N1 may include a first-first node electrode NE1-1, a first-second node electrode NE1-2 located on the first-first node electrode NE1-1, and a first-third node electrode NE1-3 located on the first-second node electrode NE1-2. The above-described first-first, first-second, and first-third node electrodes NE1-1, NE1-2, and NE1-3 may be connected to each other.

The first capacitor C1 may include the first capacitor electrode CPE1 and the second capacitor electrode CPE2 located adjacent to each other in the horizontal direction (e.g., in the first direction DR1 and/or the second direction DR2).

The second capacitor C2 may include the third capacitor electrode and the fourth capacitor electrode located adjacent to each other in the horizontal direction (e.g., in the first direction DR1 and/or the second direction DR2).

As illustrated in FIGS. 8 to 11, the first capacitor electrode CPE1 may include a plurality of sub-capacitor electrodes located adjacent to each other in the vertical direction (e.g., the third direction DR3). For example, the first capacitor electrode CPE1 may include a plurality of first-first sub-capacitor electrodes SUE1-1, a plurality of first-second sub-capacitor electrodes SUE1-2 located on the plurality of first-first sub-capacitor electrodes SUE1-1, a plurality of first-third sub-capacitor electrodes SUE1-3 located on the plurality of first-second sub-capacitor electrodes SUE1-2, and a plurality of first-fourth sub-capacitor electrodes SUE1-4 located on the plurality of first-third sub-capacitor electrodes SUE1-3. The first-first, first-second, first-third, and first-fourth sub-capacitor electrodes SUE1-1, SUE1-2, SUE1-3, and SUE1-4 may be connected to each other.

As illustrated in FIGS. 8 to 11, the second capacitor electrode CPE2 may include a plurality of sub-capacitor electrodes located adjacent to each other in the vertical direction (e.g., the third direction DR3). For example, the second capacitor electrode CPE2 may include a plurality of second-first sub-capacitor electrodes SUE2-1, a plurality of second-second sub-capacitor electrodes SUE2-2 located on the plurality of second-first sub-capacitor electrodes SUE2-1, a plurality of second-third sub-capacitor electrodes SUE2-3 located on the plurality of second-second sub-capacitor electrodes SUE2-2, and a plurality of second-fourth sub-capacitor electrodes SUE2-4 located on the plurality of second-third sub-capacitor electrodes SUE2-3. The second-first, second-second, second-third, and second-fourth sub-capacitor electrodes SUE2-1, SUE2-2, SUE2-3, and SUE2-4 may be connected to each other.

As illustrated in FIGS. 8 to 11, the third capacitor electrode may include a plurality of sub-capacitor electrodes located adjacent to each other in the vertical direction (e.g., the third direction DR3). For example, the third capacitor electrode may include a plurality of third-first sub-capacitor electrodes SUE3-1, a plurality of third-second sub-capacitor electrodes SUE3-2 located on the plurality of third-first sub-capacitor electrodes SUE3-1, a plurality of third-third sub-capacitor electrodes SUE3-3 located on the plurality of third-second sub-capacitor electrodes SUE3-2, and a plurality of third-fourth sub-capacitor electrodes SUE3-4 located on the plurality of third-third sub-capacitor electrodes SUE3-3. The third-first, third-second, third-third, and third-fourth sub-capacitor electrodes SUE3-1, SUE3-2, SUE3-3, and SUE3-4 may be connected to each other.

As illustrated in FIGS. 8 to 11, the fourth capacitor electrode may include a plurality of sub-capacitor electrodes located adjacent to each other in the vertical direction (e.g., the third direction DR3). For example, the fourth capacitor electrode may include a plurality of fourth-first sub-capacitor electrodes SUE4-1, a plurality of fourth-second sub-capacitor electrodes SUE4-2 located on the plurality of fourth-first sub-capacitor electrodes SUE4-1, a plurality of fourth-third sub-capacitor electrodes SUE4-3 located on the plurality of fourth-second sub-capacitor electrodes SUE4-2, and a plurality of fourth-fourth sub-capacitor electrodes SUE4-4 located on the plurality of fourth-third sub-capacitor electrodes SUE4-3. The fourth-first, fourth-second, fourth-third, and fourth-fourth sub-capacitor electrodes SUE4-1, SUE4-2, SUE4-3, and SUE4-4 may be connected to each other.

As illustrated in FIG. 8, the first-first sub-capacitor electrodes SUE1-1 may each extend along the second direction DR2. The first-first sub-capacitor electrodes SUE1-1 may be arranged along the first direction DR1. Respective sides of the first-first sub-capacitor electrodes SUE1-1 may be connected to each other. For example, respective sides of the plurality of first-first sub-capacitor electrodes SUE1-1 may be connected to the first node N1. For example, respective sides of the plurality of first-first sub-capacitor electrodes SUE1-1 may be connected to the first-first node electrode NE1-1 of the first node N1. The first-first node electrode NE1-1 and the plurality of first-first sub-capacitor electrodes SUE1-1 may be formed integrally with each other.

As illustrated in FIG. 8, the second-first sub-capacitor electrodes SUE2-1 may each extend along the second direction DR2. The second-first sub-capacitor electrodes SUE2-1 may be arranged along the first direction DR1. Respective sides of the second-first sub-capacitor electrodes SUE2-1 may be connected to each other. For example, respective sides of the plurality of second-first sub-capacitor electrodes SUE2-1 may be connected to the second node N2.

According to one or more embodiments, as illustrated in FIG. 8, the first-first sub-capacitor electrode SUE1-1 may be located between two second-first sub-capacitor electrodes SUE2-1 adjacent to each other in the first direction DR1.

According to one or more embodiments, when the first-first sub-capacitor electrodes SUE1-1 and the second-first sub-capacitor electrodes SUE2-1 located along the first direction DR1 are defined as a first sub-capacitor electrode group, the second-first sub-capacitor electrode SUE2-1 may be located at the outermost portion of the first sub-capacitor electrode group. For example, any one second-first sub-capacitor electrode SUE2-1 located at the outermost portion of one side among the second-first sub-capacitor electrodes SUE2-1 and any one second-first sub-capacitor electrode SUE2-1 located at the outermost portion of the other side among the second-first sub-capacitor electrodes SUE2-1 may be located at the outermost portions of both sides of the first sub-capacitor electrode group, respectively. In other words, the second-first sub-capacitor electrodes SUE2-1 located at the outermost portions of both sides among the second-first sub-capacitor electrodes SUE2-1 may be located at the outermost portions of both sides of the first sub-capacitor electrode group, respectively.

In addition, as illustrated in FIG. 8, the third-first sub-capacitor electrodes SUE3-1 may each extend along the second direction DR2. The third-first sub-capacitor electrodes SUE3-1 may be arranged along the first direction DR1. Respective sides of the third-first sub-capacitor electrodes SUE3-1 may be connected to each other. For example, respective sides of the plurality of third-first sub-capacitor electrodes SUE3-1 may be connected to the first node N1. For example, respective sides of the third-first sub-capacitor electrodes SUE3-1 may be connected to the first-first node electrode NE1-1 of the first node N1. The first-first node electrode NE1-1 and the plurality of third-first sub-capacitor electrodes SUE3-1 may be formed integrally with each other.

As illustrated in FIG. 8, the fourth-first sub-capacitor electrodes SUE4-1 may each extend along the second direction DR2. The fourth-first sub-capacitor electrodes SUE4-1 may be arranged along the first direction DR1. Respective sides of the fourth-first sub-capacitor electrodes SUE4-1 may be connected to each other. For example, respective sides of the plurality of fourth-first sub-capacitor electrodes SUE4-1 may be connected to the reference voltage line VRL.

According to one or more embodiments, as illustrated in FIG. 8, the third-first sub-capacitor electrode SUE3-1 may be located between two fourth-first sub-capacitor electrodes SUE4-1 adjacent to each other in the first direction DR1.

According to one or more embodiments, when the third-first sub-capacitor electrodes SUE3-1 and the fourth-first sub-capacitor electrodes SUE4-1 located along the first direction DR1 are defined as a second sub-capacitor electrode group, the fourth-first sub-capacitor electrode SUE4-1 may be located at the outermost portion of the second sub-capacitor electrode group. For example, any one fourth-first sub-capacitor electrode SUE4-1 located at the outermost portion of one side among the fourth-first sub-capacitor electrodes SUE4-1 and any one fourth-first sub-capacitor electrode SUE4-1 located at the outermost portion of the other side among the fourth-first sub-capacitor electrodes SUE4-1 may be located at the outermost portions of both sides of the second sub-capacitor electrode group, respectively. In other words, the fourth-first sub-capacitor electrodes SUE4-1 located at the outermost portions of both sides among the fourth-first sub-capacitor electrodes SUE4-1 may be located at the outermost portions of both sides of the second sub-capacitor electrode group, respectively.

The third connection electrode CNE3 may be located close to the second-first sub-capacitor electrode SUE2-1. For example, the third connection electrode CNE3 may be located adjacent to the second-first sub-capacitor electrode SUE2-1 located at the outermost portion of one side among the second-first sub-capacitor electrodes SUE2-1, in the first direction DR1.

As illustrated in FIG. 9, the first-second sub-capacitor electrodes SUE1-2 may each extend along the second direction DR2. The first-second sub-capacitor electrodes SUE1-2 may be arranged along the first direction DR1. Respective sides of the first-second sub-capacitor electrodes SUE1-2 may be connected to each other. For example, respective sides of the plurality of first-second sub-capacitor electrodes SUE1-2 may be connected to the first node N1. For example, respective sides of the plurality of first-second sub-capacitor electrodes SUE1-2 may be connected to the first-second node electrode NE1-2 of the first node N1. The first-second node electrode NE1-2 and the plurality of first-second sub-capacitor electrodes SUE1-2 may be formed integrally with each other.

As illustrated in FIG. 9, the second-second sub-capacitor electrodes SUE2-2 may each extend along the second direction DR2. The second-second sub-capacitor electrodes SUE2-2 may be arranged along the first direction DR1. Respective sides of the second-second sub-capacitor electrodes SUE2-2 may be connected to each other. For example, respective sides of the plurality of second-second sub-capacitor electrodes SUE2-2 may be connected to the second node N2.

According to one or more embodiments, as illustrated in FIG. 9, the first-second sub-capacitor electrode SUE1-2 may be located between two second-second sub-capacitor electrodes SUE2-2 adjacent to each other in the first direction DR1.

According to one or more embodiments, when the first-second sub-capacitor electrodes SUE1-2 and the second-second sub-capacitor electrodes SUE2-2 located along the first direction DR1 are defined as a third sub-capacitor electrode group, the second-second sub-capacitor electrode SUE2-2 may be located at the outermost portion of the third sub-capacitor electrode group. For example, any one second-second sub-capacitor electrode SUE2-2 located at the outermost portion of one side among the second-second sub-capacitor electrodes SUE2-2 and any one second-second sub-capacitor electrode SUE2-2 located at the outermost portion of the other side among the second-second sub-capacitor electrodes SUE2-2 may be located at the outermost portions of both sides of the third sub-capacitor electrode group, respectively. In other words, the second-second sub-capacitor electrodes SUE2-2 located at the outermost portions of both sides among the second-second sub-capacitor electrodes SUE2-2 may be located at the outermost portions of both sides of the third sub-capacitor electrode group, respectively.

In addition, as illustrated in FIG. 9, the third-second sub-capacitor electrodes SUE3-2 may each extend along the second direction DR2. The third-second sub-capacitor electrodes SUE3-2 may be arranged along the first direction DR1. Respective sides of the third-second sub-capacitor electrodes SUE3-2 may be connected to each other. For example, respective sides of the plurality of third-second sub-capacitor electrodes SUE3-2 may be connected to the first node N1. For example, respective sides of the third-second sub-capacitor electrodes SUE3-2 may be connected to the first-second node electrode NE1-2 of the first node N1. The first-second node electrode NE1-2 and the plurality of third-second sub-capacitor electrodes SUE3-2 may be formed integrally with each other.

As illustrated in FIG. 9, the fourth-second sub-capacitor electrodes SUE4-2 may each extend along the second direction DR2. The fourth-second sub-capacitor electrodes SUE4-2 may be arranged along the first direction DR1. Respective sides of the fourth-second sub-capacitor electrodes SUE4-2 may be connected to each other. For example, respective sides of the plurality of fourth-second sub-capacitor electrodes SUE4-2 may be connected to the reference voltage line VRL.

According to one or more embodiments, as illustrated in FIG. 9, the third-second sub-capacitor electrode SUE3-2 may be located between two fourth-second sub-capacitor electrodes SUE4-2 adjacent to each other in the first direction DR1.

According to one or more embodiments, when the third-second sub-capacitor electrodes SUE3-2 and the fourth-second sub-capacitor electrodes SUE4-2 located along the first direction DR1 are defined as a fourth sub-capacitor electrode group, the fourth-second sub-capacitor electrode SUE4-2 may be located at the outermost portion of the fourth sub-capacitor electrode group. For example, any one fourth-second sub-capacitor electrode SUE4-2 located at the outermost portion of one side among the fourth-second sub-capacitor electrodes SUE4-2 and any one fourth-second sub-capacitor electrode SUE4-2 located at the outermost portion of the other side among the fourth-second sub-capacitor electrodes SUE4-2 may be located at the outermost portions of both sides of the fourth sub-capacitor electrode group, respectively. In other words, the fourth-second sub-capacitor electrodes SUE4-2 located at the outermost portions of both sides among the fourth-second sub-capacitor electrodes SUE4-2 may be located at the outermost portions of both sides of the fourth sub-capacitor electrode group, respectively.

The first sub-data line SDL1 may be located close to the second-second sub-capacitor electrode SUE2-2 and the fourth-second sub-capacitor electrode SUE4-2. For example, the first sub-data line SDL1 may be located adjacent to the second-second sub-capacitor electrode SUE2-2 located at the outermost portion of one side among the second-second sub-capacitor electrodes SUE2-2, and adjacent to the fourth-second sub-capacitor electrode SUE4-2 located at the outermost portion of one side among the fourth-second sub-capacitor electrodes SUE4-2, in the first direction DR1.

As illustrated in FIG. 10, the first-third sub-capacitor electrodes SUE1-3 may each extend along the second direction DR2. The first-third sub-capacitor electrodes SUE1-3 may be arranged along the first direction DR1. Respective sides of the first-third sub-capacitor electrodes SUE1-3 may be connected to each other. For example, respective sides of the plurality of first-third sub-capacitor electrodes SUE1-3 may be connected to the first node N1. For example, respective sides of the plurality of first-third sub-capacitor electrodes SUE1-3 may be connected to the first-third node electrode NE1-3 of the first node N1. The first-third node electrode NE1-3 and the plurality of first-third sub-capacitor electrodes SUE1-3 may be formed integrally with each other.

As illustrated in FIG. 10, the second-third sub-capacitor electrodes SUE2-3 may each extend along the second direction DR2. The second-third sub-capacitor electrodes SUE2-3 may be arranged along the first direction DR1. Respective sides of the second-third sub-capacitor electrodes SUE2-3 may be connected to each other. For example, respective sides of the plurality of second-third sub-capacitor electrodes SUE2-3 may be connected to the second node N2.

According to one or more embodiments, as illustrated in FIG. 10, the first-third sub-capacitor electrode SUE1-3 may be located between two second-third sub-capacitor electrodes SUE2-3 adjacent to each other in the first direction DR1.

According to one or more embodiments, when the first-third sub-capacitor electrodes SUE1-3 and the second-third sub-capacitor electrodes SUE2-3 located along the first direction DR1 are defined as a fifth sub-capacitor electrode group, the second-third sub-capacitor electrode SUE2-3 may be located at the outermost portion of the fifth sub-capacitor electrode group. For example, any one second-third sub-capacitor electrode SUE2-3 located at the outermost portion of one side among the second-third sub-capacitor electrodes SUE2-3 and any one second-third sub-capacitor electrode SUE2-3 located at the outermost portion of the other side among the second-third sub-capacitor electrodes SUE2-3 may be located at the outermost portions of both sides of the fifth sub-capacitor electrode group, respectively. In other words, the second-third sub-capacitor electrodes SUE2-3 located at the outermost portions of both sides among the second-third sub-capacitor electrodes SUE2-3 may be located at the outermost portions of both sides of the fifth sub-capacitor electrode group, respectively.

In addition, as illustrated in FIG. 10, the third-third sub-capacitor electrodes SUE3-3 may each extend along the second direction DR2. The third-third sub-capacitor electrodes SUE3-3 may be arranged along the first direction DR1. Respective sides of the third-third sub-capacitor electrodes SUE3-3 may be connected to each other. For example, respective sides of the plurality of third-third sub-capacitor electrodes SUE3-3 may be connected to the first node N1. For example, respective sides of the third-third sub-capacitor electrodes SUE3-3 may be connected to the first-third node electrode NE1-3 of the first node N1. The first-third node electrode NE1-3 and the plurality of third-third sub-capacitor electrodes SUE3-3 may be formed integrally with each other.

As illustrated in FIG. 10, the fourth-third sub-capacitor electrodes SUE4-3 may each extend along the second direction DR2. The fourth-third sub-capacitor electrodes SUE4-3 may be arranged along the first direction DR1. Respective sides of the fourth-third sub-capacitor electrodes SUE4-3 may be connected to each other. For example, respective sides of the plurality of fourth-third sub-capacitor electrodes SUE4-3 may be connected to the reference voltage line VRL.

According to one or more embodiments, as illustrated in FIG. 10, the third-third sub-capacitor electrode SUE3-3 may be located between two fourth-third sub-capacitor electrodes SUE4-3 adjacent to each other in the first direction DR1.

According to one or more embodiments, when the third-third sub-capacitor electrodes SUE3-3 and the fourth-third sub-capacitor electrodes SUE4-3 located along the first direction DR1 are defined as a sixth sub-capacitor electrode group, the fourth-third sub-capacitor electrode SUE4-3 may be located at the outermost portion of the sixth sub-capacitor electrode group. For example, any one fourth-third sub-capacitor electrode SUE4-3 located at the outermost portion of one side among the fourth-third sub-capacitor electrodes SUE4-3 and any one fourth-third sub-capacitor electrode SUE4-3 located at the outermost portion of the other side among the fourth-third sub-capacitor electrodes SUE4-3 may be located at the outermost portions of both sides of the sixth sub-capacitor electrode group, respectively. In other words, the fourth-third sub-capacitor electrodes SUE4-3 located at the outermost portions of both sides among the fourth-third sub-capacitor electrodes SUE4-3 may be located at the outermost portions of both sides of the sixth sub-capacitor electrode group, respectively.

The second sub-data line SDL2 may be located close to the second-third sub-capacitor electrode SUE2-3 and the fourth-third sub-capacitor electrode SUE4-3. For example, the second sub-data line SDL2 may be located adjacent to the second-third sub-capacitor electrode SUE2-3 located at the outermost portion of one side among the second-third sub-capacitor electrodes SUE2-3, and adjacent to the fourth-third sub-capacitor electrode SUE4-3 located at the outermost portion of one side among the fourth-third sub-capacitor electrodes SUE4-3, in the first direction DR1.

As illustrated in FIG. 11, the first-fourth sub-capacitor electrodes SUE1-4 may each extend along the second direction DR2. The first-fourth sub-capacitor electrodes SUE1-4 may be arranged along the first direction DR1. Respective sides of the first-fourth sub-capacitor electrodes SUE1-4 may be connected to each other. For example, respective sides of the plurality of first-fourth sub-capacitor electrodes SUE1-4 may be connected to the first node N1. For example, respective sides of the plurality of first-fourth sub-capacitor electrodes SUE1-4 may be connected to the first-third node electrode NE1-3 of the first node N1.

As illustrated in FIG. 11, the second-fourth sub-capacitor electrodes SUE2-4 may each extend along the second direction DR2. The second-fourth sub-capacitor electrodes SUE2-4 may be arranged along the first direction DR1. Respective sides of the second-fourth sub-capacitor electrodes SUE2-4 may be connected to each other. For example, respective sides of the plurality of second-fourth sub-capacitor electrodes SUE2-4 may be connected to the second node N2.

According to one or more embodiments, as illustrated in FIG. 11, the first-fourth sub-capacitor electrode SUE1-4 may be located between two second-fourth sub-capacitor electrodes SUE2-4 adjacent to each other in the first direction DR1.

According to one or more embodiments, when the first-fourth sub-capacitor electrodes SUE1-4 and the second-fourth sub-capacitor electrodes SUE2-4 located along the first direction DR1 are defined as a seventh sub-capacitor electrode group, the second-fourth sub-capacitor electrode SUE2-4 may be located at the outermost portion of the seventh sub-capacitor electrode group. For example, any one second-fourth sub-capacitor electrode SUE2-4 located at the outermost portion of one side among the second-fourth sub-capacitor electrodes SUE2-4 and any one second-fourth sub-capacitor electrode SUE2-4 located at the outermost portion of the other side among the second-fourth sub-capacitor electrodes SUE2-4 may be located at the outermost portions of both sides of the seventh sub-capacitor electrode group, respectively. In other words, the second-fourth sub-capacitor electrodes SUE2-4 located at the outermost portions of both sides among the second-fourth sub-capacitor electrodes SUE2-4 may be located at the outermost portions of both sides of the seventh sub-capacitor electrode group, respectively.

In addition, as illustrated in FIG. 11, the third-fourth sub-capacitor electrodes SUE3-4 may each extend along the second direction DR2. The third-fourth sub-capacitor electrodes SUE3-4 may be arranged along the first direction DR1. Respective sides of the third-fourth sub-capacitor electrodes SUE3-4 may be connected to each other. For example, respective sides of the plurality of third-fourth sub-capacitor electrodes SUE3-4 may be connected to the first node N1. For example, respective sides of the third-fourth sub-capacitor electrodes SUE3-4 may be connected to the first-third node electrode NE1-3 of the first node N1.

As illustrated in FIG. 11, the fourth-fourth sub-capacitor electrodes SUE4-4 may each extend along the second direction DR2. The fourth-fourth sub-capacitor electrodes SUE4-4 may be arranged along the first direction DR1. Respective sides of the fourth-fourth sub-capacitor electrodes SUE4-4 may be connected to each other. For example, respective sides of the plurality of fourth-fourth sub-capacitor electrodes SUE4-4 may be connected to the reference voltage line VRL.

According to one or more embodiments, as illustrated in FIG. 11, the third-fourth sub-capacitor electrode SUE3-4 may be located between two fourth-fourth sub-capacitor electrodes SUE4-4 adjacent to each other in the first direction DR1.

According to one or more embodiments, when the third-fourth sub-capacitor electrodes SUE3-4 and the fourth-fourth sub-capacitor electrodes SUE4-4 located along the first direction DR1 are defined as an eighth sub-capacitor electrode group, the fourth-fourth sub-capacitor electrode SUE4-4 may be located at the outermost portion of the eighth sub-capacitor electrode group. For example, any one fourth-fourth sub-capacitor electrode SUE4-4 located at the outermost portion of one side among the fourth-fourth sub-capacitor electrodes SUE4-4 and any one fourth-fourth sub-capacitor electrode SUE4-4 located at the outermost portion of the other side among the fourth-fourth sub-capacitor electrodes SUE4-4 may be located at the outermost portions of both sides of the eighth sub-capacitor electrode group, respectively. In other words, the fourth-fourth sub-capacitor electrodes SUE4-4 located at the outermost portions of both sides among the fourth-fourth sub-capacitor electrodes SUE4-4 may be located at the outermost portions of both sides of the eighth sub-capacitor electrode group, respectively.

As illustrated in FIG. 12, a first insulating film INS1′ may be located on the semiconductor backplane SBP. Here, the semiconductor backplane SBP may include a transistor region TRA in which the pixel transistors PTR as described above are located.

A first conductive layer including a first connection electrode CNE1, the write scan line GWL, and an emission control line EL may be located on the first insulating film INS1′. Meanwhile, the above-described bias scan line EBL may be further located at the first conductive layer. At least one of components of the first conductive layer may be connected to at least one of the pixel transistors of the transistor region TRA through a first via VA1′. For example, the first connection electrode CNE1, which is any one of the components of the first conductive layer, may be connected to the source electrode of the second transistor T2 through the first via VA1′.

A second insulating film INS2′ may be located on the first conductive layer.

A second conductive layer including the initialization voltage line VIL and the driving voltage line VDL may be located on the second insulating film INS2′. At least one of components of the second conductive layer may be connected to the first conductive layer through a second via VA2′. For example, a second connection electrode CNE2, which is any one of the components of the second conductive layer, may be connected to the first connection electrode CNE1 through the second via VA2′.

A third insulating film INS3′ may be located on the second conductive layer.

A third conductive layer including the third connection electrode CNE3, the plurality of second-first sub-capacitor electrodes SUE2-1, and the plurality of first-first sub-capacitor electrodes SUE1-1 may be located on the third insulating film INS3′. According to one or more embodiments, the second-first sub-capacitor electrodes SUE2-1 and the first-first sub-capacitor electrodes SUE1-1 on the third insulating film INS3′ may be alternately located along the first direction DR1. In this case, the second-first sub-capacitor electrodes SUE2-1 among the sub-capacitor electrodes on the third insulating film INS3′ may be located at the outermost portions. For example, when the second-first sub-capacitor electrodes SUE2-1 and the first-first sub-capacitor electrodes SUE1-1 are defined as the first sub-capacitor electrode group as described above, the second-first sub-capacitor electrodes SUE2-1 may be located at the outermost portions in the first sub-capacitor electrode group. At least one of components of the third conductive layer may be connected to the second conductive layer through a third via VA3′. For example, the third connection electrode CNE3, which is any one of the components of the third conductive layer, may be connected to the second connection electrode CNE2 through the third via VA3′.

A fourth insulating film INS4′ may be located on the third conductive layer.

A fourth conductive layer including the first sub-data line SDL1, the plurality of second-second sub-capacitor electrodes SUE2-2, and the plurality of first-second sub-capacitor electrodes SUE1-2 may be located on the fourth insulating film INS4′. According to one or more embodiments, the second-second sub-capacitor electrodes SUE2-2 and the first-second sub-capacitor electrodes SUE1-2 on the fourth insulating film INS4′ may be alternately located along the first direction DR1. In this case, the second-second sub-capacitor electrodes SUE2-2 among the sub-capacitor electrodes on the fourth insulating film INS4′ may be located at the outermost portions. For example, when the second-second sub-capacitor electrodes SUE2-2 and the first-second sub-capacitor electrodes SUE1-2 are defined as the third sub-capacitor electrode group as described above, the second-second sub-capacitor electrodes SUE2-2 may be located at the outermost portions in the third sub-capacitor electrode group. At least one of components of the fourth conductive layer may be connected to the third conductive layer through a fourth via VA4′. For example, the first sub-data line SDL1, which is any one of the components of the fourth conductive layer, may be connected to the third connection electrode CNE3 through the fourth via VA4′.

A fifth insulating film INS5′ may be located on the fourth conductive layer.

A fifth conductive layer including the second sub-data line SDL2, the plurality of second-third sub-capacitor electrodes SUE2-3, and the plurality of first-third sub-capacitor electrodes SUE1-3 may be located on the fifth insulating film INS5′. According to one or more embodiments, the second-third sub-capacitor electrodes SUE2-3 and the first-third sub-capacitor electrodes SUE1-3 on the fifth insulating film INS5′ may be alternately located along the first direction DR1. In this case, the second-third sub-capacitor electrodes SUE2-3 among the sub-capacitor electrodes on the fifth insulating film INS5′ may be located at the outermost portions. For example, when the second-third sub-capacitor electrodes SUE2-3 and the first-third sub-capacitor electrodes SUE1-3 are defined as the fifth sub-capacitor electrode group as described above, the second-third sub-capacitor electrodes SUE2-3 may be located at the outermost portions in the fifth sub-capacitor electrode group. At least one of components of the fifth conductive layer may be connected to the fourth conductive layer through a fifth via VA5′. For example, the second sub-data line SDL2, which is any one of the components of the fifth conductive layer, may be connected to the first sub-data line SDL1 through the fifth via VA5′.

A sixth insulating film INS6′ may be located on the fifth conductive layer.

A sixth conductive layer including the plurality of second-fourth sub-capacitor electrodes SUE2-4 and the plurality of first-fourth sub-capacitor electrodes SUE1-4 may be located on the sixth insulating film INS6′. According to one or more embodiments, the second-fourth sub-capacitor electrodes SUE2-4 and the first-fourth sub-capacitor electrodes SUE1-4 on the sixth insulating film INS6′ may be alternately located along the first direction DR1. In this case, the second-fourth sub-capacitor electrodes SUE2-4 among the sub-capacitor electrodes on the sixth insulating film INS6′ may be located at the outermost portions. For example, when the second-fourth sub-capacitor electrodes SUE2-4 and the first-fourth sub-capacitor electrodes SUE1-4 are defined as the seventh sub-capacitor electrode group as described above, the second-fourth sub-capacitor electrodes SUE2-4 may be located at the outermost portions in the seventh sub-capacitor electrode group.

Sub-capacitor electrodes overlapping each other in the third direction DR3 among the sub-capacitor electrodes of the first capacitor C1 may be electrically connected to each other. For example, the second-first, second-second, second-third, and second-fourth sub-capacitor electrodes SUE2-1, SUE2-2, SUE2-3, and SUE2-4 that overlap each other in the third direction DR3 may be connected to each other. In addition, the first-first, first-second, first-third, and first-fourth sub-capacitor electrodes SUE1-1, SUE1-2, SUE1-3, and SUE1-4 that overlap each other in the third direction DR3 may be connected to each other.

Sub-capacitor electrodes overlapping each other in the third direction DR3 among the sub-capacitor electrodes of the second capacitor C2 may be electrically connected to each other. For example, the third-first, third-second, third-third, and third-fourth sub-capacitor electrodes SUE3-1, SUE3-2, SUE3-3, and SUE3-4 that overlap each other in the third direction DR3 may be connected to each other. In addition, the fourth-first, fourth-second, fourth-third, and fourth-fourth sub-capacitor electrodes SUE4-1, SUE4-2, SUE4-3, and SUE4-4 that overlap each other in the third direction DR3 may be connected to each other.

According to one or more embodiments, for example, the first capacitor electrode CPE1 connected to a gate node (e.g., the first node N1) of the driving transistor (e.g., T1) may be shielded by the second capacitor electrode CPE2. In other words, the outermost sub-capacitor electrodes of the second capacitor electrode CPE2 are located outside than the outermost sub-capacitor electrodes of the first capacitor electrode CPE1, and accordingly, the outermost sub-capacitor electrode of the second capacitor electrode CPE2 may be located between the outermost sub-capacitor electrode of the first capacitor C1 and the data line (e.g., the first sub-data line SDL1 or the second sub-data line SDL2). Therefore, the second capacitor electrode CPE2 may reduce or prevent the likelihood of coupling between the first capacitor electrode CPE1 connected to the gate node and the data line (e.g., coupling between the first capacitor electrode CPE1 and the data line DL due to a parasitic capacitor between the first capacitor electrode CPE1 and the data line DL). Accordingly, in spite of a change in voltage of the data line DL, a voltage of the first capacitor electrode CPE1 may be stably maintained. Ultimately, a voltage of the gate node (e.g., the first node N1) may be stably maintained regardless of the change in the voltage of the data line DL, and thus, a fluctuation in the driving current flowing through the driving transistor connected to the gate node may be reduced or minimized. Accordingly, image quality of the display device may be improved.

As an example, as illustrated in FIG. 12, when one first-second sub-capacitor electrode SUE1-2 closest to the first sub-data line SDL1 in the first direction DR1 among four first-second sub-capacitor electrodes SUE1-2 is defined as a first outermost sub-capacitor electrode, and when one second-second sub-capacitor electrode SUE2-2 closest to the first sub-data line SDL1 among five second-second sub-capacitor electrodes SUE2-2 is defined as a second outermost sub-capacitor electrode, the second outermost sub-capacitor electrode may be located between the first sub-data line SDL1 and the first outermost sub-capacitor electrode. In other words, when one first-second sub-capacitor electrode SUE1-2 located at the outermost portion of one side among the four first-second sub-capacitor electrodes SUE1-2 is defined as the first outermost sub-capacitor electrode described above, and when one second-second sub-capacitor electrode SUE2-2 located at the outermost portion of one side among the five second-second sub-capacitor electrodes SUE2-2 is defined as the second outermost sub-capacitor electrode described above, the second outermost sub-capacitor electrode may be located between the first sub-data line SDL1 and the first outermost sub-capacitor electrode. Accordingly, the likelihood of coupling between the first outermost sub-capacitor electrode and the first sub-data line SDL1 may be reduced or prevented by the second outermost sub-capacitor electrode. Therefore, in spite of a change in voltage of the first sub-data line SDL1, voltages of the first-second sub-capacitor electrodes SUE1-2 and the gate node connected to the first-second sub-capacitor electrodes SUE1-2 may be stably maintained.

As another example, as illustrated in FIG. 12, when one first-third sub-capacitor electrode SUE1-3 closest to the second sub-data line SDL2 in the first direction DR1 among four first-third sub-capacitor electrodes SUE1-3 is defined as a third outermost sub-capacitor electrode, and when one second-third sub-capacitor electrode SUE2-3 closest to the second sub-data line SDL2 among five second-third sub-capacitor electrodes SUE2-3 is defined as a fourth outermost sub-capacitor electrode, the fourth outermost sub-capacitor electrode may be located between the second sub-data line SDL2 and the third outermost sub-capacitor electrode. In other words, when one first-third sub-capacitor electrode SUE1-3 located at the outermost portion of one side among the four first-third sub-capacitor electrodes SUE1-3 is defined as the third outermost sub-capacitor electrode described above, and when one second-third sub-capacitor electrode SUE2-3 located at the outermost portion of one side among the five second-third sub-capacitor electrodes SUE2-3 is defined as the fourth outermost sub-capacitor electrode described above, the fourth outermost sub-capacitor electrode may be located between the second sub-data line SDL2 and the third outermost sub-capacitor electrode. Accordingly, coupling between the third outermost sub-capacitor electrode and the second sub-data line SDL2 may be reduced or prevented by the fourth outermost sub-capacitor electrode. Therefore, in spite of a change in voltage of the second sub-data line SDL2, voltages of the first-third sub-capacitor electrodes SUE1-3 and the gate node connected to the first-third sub-capacitor electrodes SUE1-3 may be stably maintained.

Meanwhile, when one first-second sub-capacitor electrode SUE1-2 located at the outermost portion of the other side among the four first-second sub-capacitor electrodes SUE1-2 is defined as a fifth outermost sub-capacitor electrode, and when one second-second sub-capacitor electrode SUE2-2 located at the outermost portion of the other side among the five second-second sub-capacitor electrodes SUE2-2 is defined as a sixth outermost sub-capacitor electrode, the four first-second sub-capacitor electrodes SUE1-2 described above may be located between the second outermost sub-capacitor electrode described above and the sixth outermost sub-capacitor electrode.

Meanwhile, when one first-third sub-capacitor electrode SUE1-3 located at the outermost portion of the other side among the four first-third sub-capacitor electrodes SUE1-3 is defined as a seventh outermost sub-capacitor electrode, and when one second-third sub-capacitor electrode SUE2-3 located at the outermost portion of the other side among the five second-third sub-capacitor electrodes SUE2-3 is defined as an eighth outermost sub-capacitor electrode, the four first-third sub-capacitor electrodes SUE1-3 described above may be located between the fourth outermost sub-capacitor electrode described above and the eighth outermost sub-capacitor electrode.

In addition, as illustrated in FIG. 12, a power line (e.g., the initialization voltage line VIL) is connected between the data line (e.g., the first sub-data line SDL1) and the scan line (e.g., the write scan line GWL). The likelihood of coupling between the data line DL and the scan line may be reduced or prevented by the power line. Accordingly, an RC delay of a data signal (e.g., a data signal of the data line DL) due to such coupling may be reduced or minimized.

Meanwhile, as illustrated in FIG. 12, the data line DL may further include a third sub-data line SDL3. For example, the data line DL may include the first sub-data line SDL1, the second sub-data line SDL2, and the third sub-data line SDL3 connected to each other through vias VA5′ and VA6′.

The third sub-data line SDL3 may be located at the same layer as the second-fourth sub-capacitor electrode SUE2-4. For example, the third sub-data line SDL3 may be located on the sixth insulating film INS6′.

According to one or more embodiments, the data line may include a plurality of sub-data lines connected to each other in the third direction DR3. In such a case, resistance of the data line may be reduced, such that the RC delay of the data signal may be further reduced or minimized.

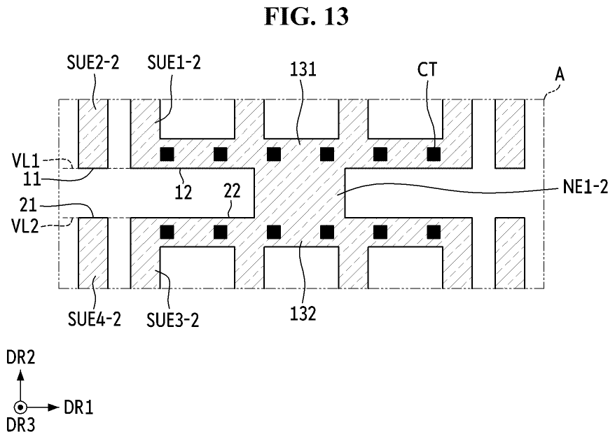

FIG. 13 is an enlarged view of area A of FIG. 9.

As illustrated in FIG. 13, an end 11 of the second-second sub-capacitor electrode SUE2-2 positioned at the outermost portion among the plurality of second-second sub-capacitor electrodes SUE2-2, and an end 12 of a first connection portion 131 between the plurality of first-second sub-capacitor electrodes SUE1-2, may coincide with each other. For example, the end 11 of the second-second sub-capacitor electrode SUE2-2 positioned at the outermost portion and the end 12 of the first connection portion 131 may be located on a virtual first line VL1. Accordingly, the first connection portion 131 between the first-second sub-capacitor electrodes SUE1-2 may be shielded by the outermost second-second sub-capacitor electrode SUE2-2.

In addition, as illustrated in FIG. 13, an end 21 of the fourth-second sub-capacitor electrode SUE4-2 positioned at the outermost portion among the plurality of fourth-second sub-capacitor electrodes SUE4-2 and an end 22 of a second connection portion 132 between the plurality of third-second sub-capacitor electrodes SUE3-2 may coincide with each other. For example, the end 21 of the fourth-second sub-capacitor electrode SUE4-2 positioned at the outermost portion and the end 22 of the second connection portion 132 may be located on a virtual second line VL2. Accordingly, the second connection portion 132 between the third-second sub-capacitor electrodes SUE3-2 may be shielded by the outermost fourth-second sub-capacitor electrode SUE4-2.

Meanwhile, the first connection portion 131 and the second connection portion 132 may be connected to the first-third sub-capacitor electrodes SUE1-3 and the third-third sub-capacitor electrode SUE3-3 through contact holes CT of an insulating film.

Meanwhile, each of the first-third sub-capacitor electrodes SUE1-3, the second-third sub-capacitor electrodes SUE2-3, the third-third sub-capacitor electrodes SUE3-3, and the fourth-third sub-capacitor electrodes SUE4-3 of FIG. 10 may also have the same configuration as that described above with reference to FIG. 13.

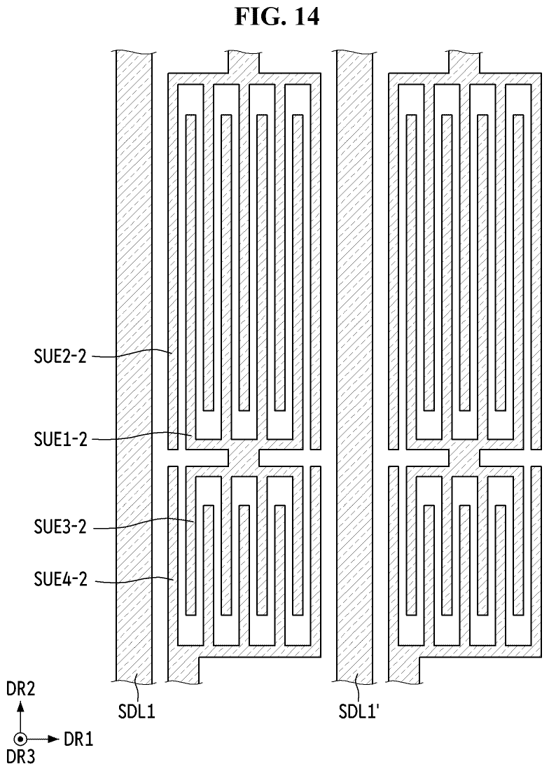

FIG. 14 is a view for describing an arrangement of sub-capacitor electrodes between a plurality of data lines adjacent to each other.

As illustrated in FIG. 14, a second-second sub-capacitor electrode SUE2-2 positioned at the outermost portion of one side among the plurality of second-second sub-capacitor electrodes SUE2-2 may be located adjacent to a first sub-data line SDL1 of a first data line, and another second-second sub-capacitor electrode SUE2-2 positioned at the outermost portion of the other side among the plurality of second-second sub-capacitor electrodes SUE2-2 may be located adjacent to a first sub-data line SDL1′ of a second data line.

As illustrated in FIG. 14, a fourth-second sub-capacitor electrode SUE4-2 positioned at the outermost portion of one side among the plurality of fourth-second sub-capacitor electrodes SUE4-2 may be located adjacent to the first sub-data line SDL1 of the first data line, and another fourth-second sub-capacitor electrode SUE4-2 positioned at the outermost portion of the other side among the plurality of fourth-second sub-capacitor electrodes SUE4-2 may be located adjacent to the first sub-data line SDL1′ of the second data line.

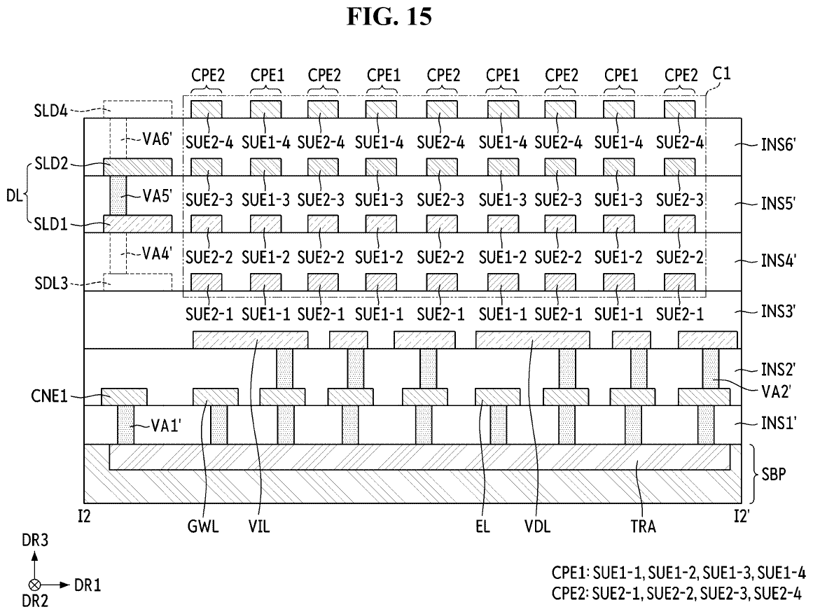

FIG. 15 is a cross-sectional view of a display panel according to one or more other embodiments.

A display panel 100 of FIG. 15 is different from the display panel 100 described above with reference to FIG. 12 in arrangement positions of sub-data lines, and such differences will be mainly described below.

As illustrated in FIG. 15, the data line DL may include a first sub-data line SDL1 and a second sub-data line SDL2. Meanwhile, the data line DL may further include at least one of a third sub-data line SDL3 and a fourth sub-data line SDL4. For example, the data line DL may include the first sub-data line SDL1, the second sub-data line SDL2, the third sub-data line SDL3, and the fourth sub-data line SDL4 connected to each other through vias VA4′, VA5′, and VA6′.

The third sub-data line SDL3 may be located at the same layer as the second-first sub-capacitor electrode SUE2-1. For example, the third sub-data line SDL3 may be located on the third insulating film INS3′.

The fourth sub-data line SDL4 may be located at the same layer as the second-fourth sub-capacitor electrode SUE2-4. For example, the fourth sub-data line SDL4 may be located on the sixth insulating film INS6′.

According to one or more embodiments, the data line DL may include a plurality of sub-data lines connected to each other in the third direction DR3. In such a case, resistance of the data line DL may be reduced, such that the RC delay of the data signal may be further reduced or minimized.

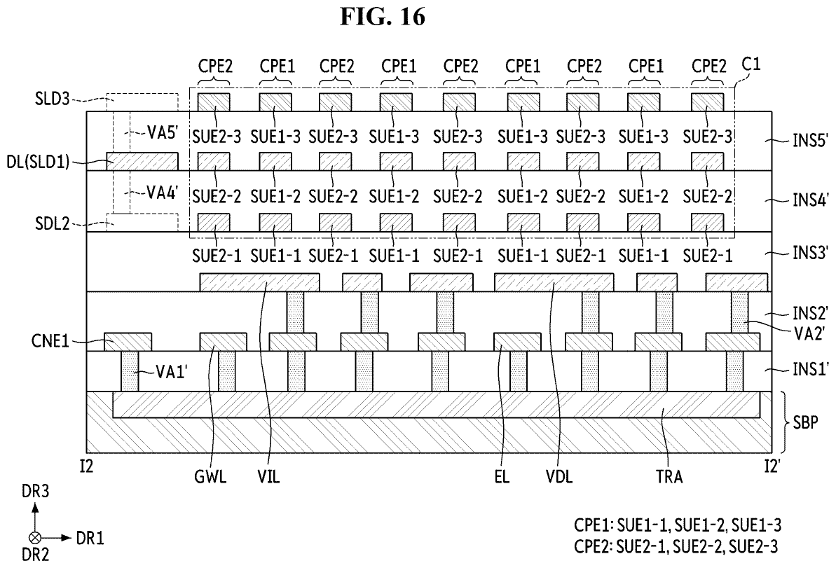

FIG. 16 is a cross-sectional view of a display panel according to still one or more other embodiments.

A display panel 100 of FIG. 16 is different from the display panel 100 described above with reference to FIG. 12 in arrangement positions of sub-data lines, and such differences will be mainly described below.

As illustrated in FIG. 16, the data line DL may include a first sub-data line SDL1 as a single sub-data line. Meanwhile, the data line DL may further include at least one of a second sub-data line SDL2 and a third sub-data line SDL3. For example, the data line may include the first sub-data line SDL1, the second sub-data line SDL2, and the third sub-data line SDL3 connected to each other through vias VA4′ and VA5′.

The second sub-data line SDL2 may be located at the same layer as the second-first sub-capacitor electrode SUE2-1. For example, the second sub-data line SDL2 may be located on the third insulating film INS3′.

The third sub-data line SDL3 may be located at the same layer as the second-third sub-capacitor electrode SUE2-3. For example, the third sub-data line SDL3 may be located on the fifth insulating film INS5′.

According to one or more embodiments, the data line DL may include a plurality of sub-data lines connected to each other in the third direction DR3. In such a case, resistance of the data line DL may be reduced, such that the RC delay of the data signal may be further reduced or minimized.

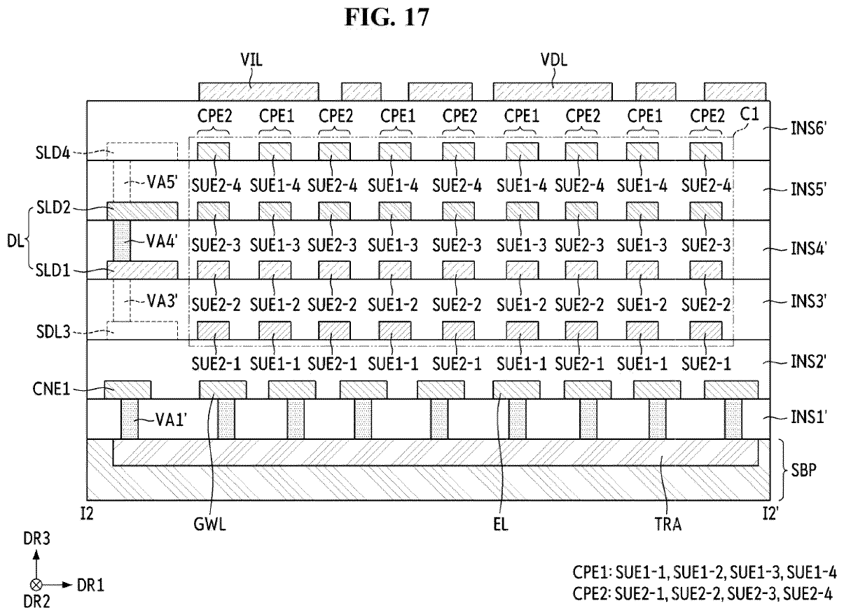

FIG. 17 is a cross-sectional view of a display panel according to still one or more other embodiments.

A display panel 100 of FIG. 17 is different from the display panel 100 described above with reference to FIG. 12 in arrangement positions of sub-data lines and an arrangement of some conductive layers, and such differences will be mainly described below.

As illustrated in FIG. 17, the data line DL may include a first sub-data line SDL1 and a second sub-data line SDL2. Meanwhile, the data line may further include at least one of a third sub-data line SDL3 and a fourth sub-data line SDL4. For example, the data line may include the first sub-data line SDL1, the second sub-data line SDL2, the third sub-data line SDL3, and the fourth sub-data line SDL4 connected to each other through vias VA3′, VA4′, and VA5′.

The third sub-data line SDL3 may be located at the same layer as the second-first sub-capacitor electrode SUE2-1. For example, the third sub-data line SDL3 may be located on the second insulating film INS2′.

The fourth sub-data line SDL4 may be located at the same layer as the second-fourth sub-capacitor electrode SUE2-4. For example, the fourth sub-data line SDL4 may be located on the fifth insulating film INS5′.

According to one or more embodiments, the data line DL may include a plurality of sub-data lines connected to each other in the third direction DR3. In such a case, resistance of the data line DL may be reduced, such that the RC delay of the data signal may be further reduced or minimized.

In addition, as illustrated in FIG. 17, the initialization voltage line VIL and the driving voltage line VDL may be located on the first capacitor C1.

Meanwhile, as in examples illustrated in FIGS. 12, 15, and 17, in cross-sectional view, the data line DL may be located at the same layer as a middle sub-capacitor electrode of the first capacitor C1. The middle sub-capacitor electrode may refer to a sub-capacitor electrode positioned in the middle in cross-sectional view among a plurality of sub-capacitor electrodes overlapping each other in the vertical direction (e.g., the third direction DR3). The middle sub-capacitor electrode in FIGS. 12, 15, and 17 may include, for example, the plurality of first-second sub-capacitor electrodes SUE1-2, the plurality of second-second sub-capacitor electrodes SUE2-2, the plurality of first-third sub-capacitor electrodes SUE1-3, and the plurality of second-third sub-capacitor electrodes SUE2-3. The first sub-data line SDL1 of the data line DL may be located at the same layer as the plurality of first-second capacitor electrodes SUE1-2 and the plurality of second-second sub-capacitor electrodes SUE2-2. In addition, the second sub-data line SDL2 of the data line DL may be located at the same layer as the plurality of first-third capacitor electrodes SUE1-3 and the plurality of second-third sub-capacitor electrodes SUE2-3.

In addition, as in an example illustrated in FIG. 16, in cross-sectional view, the data line DL may be located at the same layer as the middle sub-capacitor electrode of the first capacitor C1. Here, the middle sub-capacitor electrode in FIG. 16 may include, for example, the plurality of first-second sub-capacitor electrodes SUE1-2. The data line DL or the first sub-data line SDL1 may be located at the same layer as the plurality of first-second sub-capacitor electrodes SUE1-2.

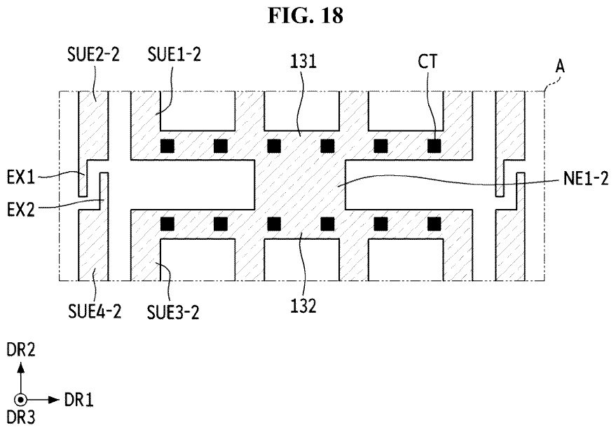

FIG. 18 is a view illustrating one or more other embodiments of a sub-capacitor electrode in the display device according to one or more embodiments. For example, FIG. 18 may be an enlarged view of one or more other embodiments of area A of FIG. 9.

The second-second sub-capacitor electrode SUE2-2 and the fourth-second sub-capacitor electrode SUE4-2 that are located at the same layer and located at the outermost portion may have a concave-convex pattern. For example, ends of the second-second sub-capacitor electrode SUE2-2 and the fourth-second sub-capacitor electrode SUE4-2 facing each other may each have a concavo-convex pattern. In this case, a concave portion of the end of the second-second sub-capacitor electrode SUE2-2 may be located to correspond to a convex portion of the end of the fourth-second sub-capacitor electrode SUE4-2, and a convex portion of the end of the second-second sub-capacitor electrode SUE2-2 may be located to correspond to a concave portion of the end of the fourth-second sub-capacitor electrode SUE4-2.

To this end, according to one or more embodiments, as illustrated in FIG. 18, the end of the second-second sub-capacitor electrode SUE2-2 may include a first extension portion EX1 extending toward the end of the fourth-second sub-capacitor electrode SUE4-2, and the end of the fourth-second sub-capacitor electrode SUE4-2 may include a second extension portion EX2 extending toward the end of the second-second sub-capacitor electrode SUE2-2. In this case, the first extension portion EX1 and the second extension portion EX2 may extend in a direction reverse to the second direction and the second direction DR2 from different areas of the respective corresponding ends, respectively, so as not to face each other. In other words, the first extension portion EX1 may be located outside the second extension portion EX2 so as to be closer to the data line DL than the second extension portion EX2 is. Meanwhile, the first extension portion EX1 and the second extension portion EX2 may face each other along the first direction DR1.

As illustrated in FIG. 18, when the second-second sub-capacitor electrode SUE2-2 and the fourth-second sub-capacitor electrode SUE4-2 include the first extension portion EX1 and the second extension portion EX2, respectively, the coupling between the connection portions 131 and 132 and an adjacent data line DL may be further reduced or minimized, such that the image quality of the display device may be further improved.

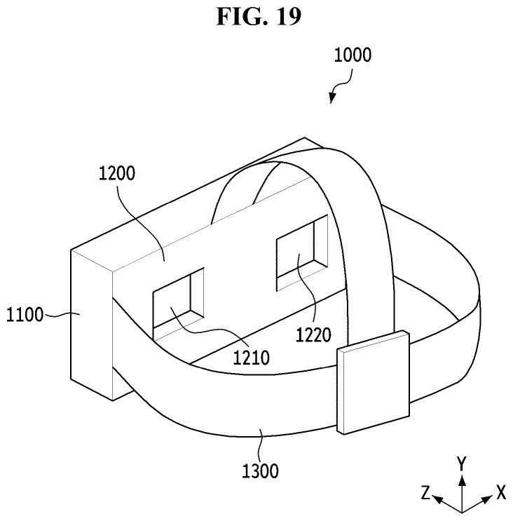

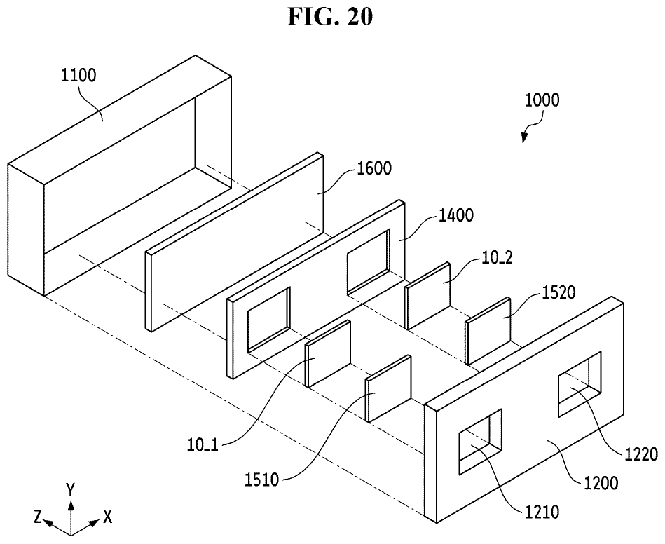

FIG. 19 is a perspective view illustrating a head-mounted display device according to one or more embodiments. FIG. 20 is an exploded perspective view illustrating an example of the head-mounted display device of FIG. 19.

Referring to FIGS. 19 and 20, a head-mounted display device 1000 according to one or more embodiments includes a first display device 10_1, a second display device 10_2, a display device housing portion 1100, a housing portion cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to a user's left eye, and the second display device 10_2 provides an image to a user's right eye. Each of the first display device 10_1 and the second display device 10_2 is substantially the same as the display device 10 described with reference to FIGS. 1 to 18, and a description of the first display device 10_1 and the second display device 10_2 is thus omitted.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and located between the second display device 10_2 and the control circuit board 1600. The middle frame 1400 serves to support and fix the first display device 10_1, the second display device 10_2, and the control circuit board 1600.

The control circuit board 1600 may be located between the middle frame 1400 and the display device housing portion 1100. The control circuit board 1600 may be connected to the first display device 10_1 and the second display device 10_2 through a connector. The control circuit board 1600 may convert an image source input from the outside into digital video data DATA, and transmit the digital video data DATA to the first display device 10_1 and the second display device 10_2 through the connector.

The control circuit board 1600 may transmit digital video data DATA corresponding to a left eye image optimized for the user's left eye to the first display device 10_1 and transmit digital video data DATA corresponding to a right eye image optimized for the user's right eye to the second display device 10_2. Alternatively, the control circuit board 1600 may transmit the same digital video data DATA to the first display device 10_1 and the second display device 10_2.

The display device housing portion 1100 serves to house the first display device 10_1, the second display device 10_2, the middle frame 1400, the first optical member 1510, the second optical member 1520, and the control circuit board 1600. The housing portion cover 1200 is located to cover opened one surface of the display device housing portion 1100. The housing portion cover 1200 may include the first eyepiece 1210 on which the user's left eye is located and the second eyepiece 1220 on which the user's right eye is located. It has been illustrated in FIGS. 19 and 20 that the first eyepiece 1210 and the second eyepiece 1220 are separately located, but one or more embodiments of the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

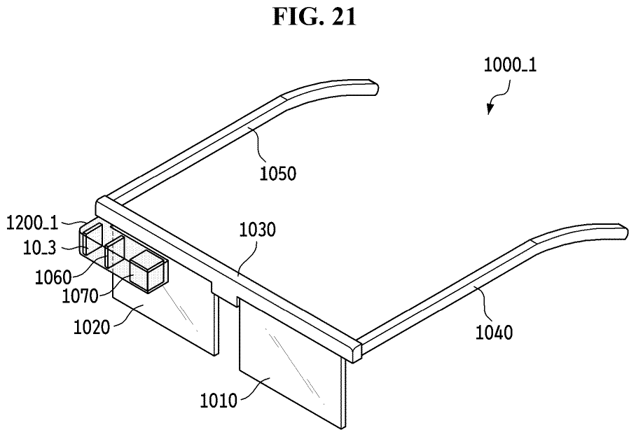

The head-mounted band 1300 serves to fix the display device housing portion 1100 to a user's head so that the first eyepiece 1210 and the second eyepiece 1220 of the housing portion cover 1200 may be maintained in a state where they are located on the user's left eye and right eye, respectively. When the display device housing portion 1200 is implemented to have a relatively light weight and a relatively small size, the head-mounted display device 1000 may include an eyeglass frame as illustrated in FIG. 21 instead of the head-mounted band 800.

In addition, the head-mounted display device 1000 may further include a battery for supplying power, an external memory slot for housing an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a wireless fidelity Wi-Fi® module, or a Bluetooth® module (Wi-Fi® being a registered trademark of the non-profit Wi-Fi Alliance, and Bluetooth® being a registered trademark of Bluetooth Sig, Inc., Kirkland, WA).

FIG. 21 is a perspective view illustrating a head-mounted display according to one or more other embodiments.

Referring to FIG. 21, a head-mounted display device 1000_1 according to one or more other embodiments may be a glasses-type display device in which a display device housing portion 1200_1 is implemented to have a light weight and a small size. The head-mounted display device 1000_1 according to one or more other embodiments may include a display device 10_3, a left eye lens 1010, a right eye lens 1020, a support frame 1030, glasses frame legs 1040 and 1050, an optical member 1060, an optical path conversion member 1070, and a display device housing portion 1200_1.

The display device housing portion 1200_1 may include the display device 10_3, the optical member 1060, and the optical path conversion member 1070. An image displayed on the display device 10_3 may be magnified by the optical member 1060, converted in an optical path by the optical path conversion member 1070, and provided to a user's right eye through the right eye lens 1020. For this reason, a user may view an augmented reality image in which a virtual image displayed on the display device 10_3 through his/her right eye and a real image seen through the right eye lens 1020 are combined with each other.

It has been illustrated in FIG. 21 that the display device housing portion 1200_1 is located at a right end of the support frame 1030, but one or more embodiments of the present disclosure is not limited thereto. For example, the display device housing portion 1200_1 may be located at a left end of the support frame 1030, and in this case, an image of the display device 10_3 may be provided to a user's left eye. Alternatively, the display device housing portions 1200_1 may be located at both the left and right ends of the support frame 1030, and in this case, the user may view an image displayed on the display device 10_3 through both his/her left and right eyes.

It will be able to be understood by one of ordinary skill in the art to which the present disclosure belongs that the present disclosure may be implemented in other specific forms without changing the technical spirit or essential features of the present disclosure. Therefore, it is to be understood that the embodiments described above are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate;
a light-emitting element above the substrate;
a transistor connected to the light-emitting element;
a first node connected to a gate electrode of the transistor; and
a capacitor connected between the first node and a second node, and comprising:
a first capacitor electrode connected to the first node and comprising first sub-capacitor electrodes; and
a second capacitor electrode connected to the second node, and comprising second sub-capacitor electrodes at a same layer as the first sub-capacitor electrodes,
wherein one of the first sub-capacitor electrodes is between adjacent ones of the second sub-capacitor electrodes.

2. The display device of claim 1, wherein the first sub-capacitor electrodes comprise a first outermost sub-capacitor electrode and a second outermost sub-capacitor electrode at respective sides of the first sub-capacitor electrodes, and
wherein the second sub-capacitor electrodes comprise a third outermost sub-capacitor electrode and a fourth outermost sub-capacitor electrode at respective sides of the second sub-capacitor electrodes.

3. The display device of claim 2, wherein the first sub-capacitor electrodes are between the third outermost sub-capacitor electrode and the fourth outermost sub-capacitor electrode.

4. The display device of claim 2, wherein the first outermost sub-capacitor electrode is between the third outermost sub-capacitor electrode and the fourth outermost sub-capacitor electrode.

5. The display device of claim 2, wherein the second outermost sub-capacitor electrode is between the third outermost sub-capacitor electrode and the fourth outermost sub-capacitor electrode.

6. The display device of claim 2, wherein the first outermost sub-capacitor electrode and the third outermost sub-capacitor electrode are adjacent to each other.

7. The display device of claim 2, wherein the second outermost sub-capacitor electrode and the fourth outermost sub-capacitor electrode are adjacent to each other.

8. The display device of claim 2, further comprising a first data line adjacent to the third outermost sub-capacitor electrode.

9. The display device of claim 8, wherein the third outermost sub-capacitor electrode is between the first data line and the first outermost sub-capacitor electrode.

10. The display device of claim 8, further comprising a second data line adjacent to the fourth outermost sub-capacitor electrode.

11. The display device of claim 10, wherein the third outermost sub-capacitor electrode is between the second outermost sub-capacitor electrode and the second data line.

12. The display device of claim 8, wherein the first capacitor electrode further comprises:
third sub-capacitor electrodes above the first sub-capacitor electrodes, and connected to the first sub-capacitor electrodes; and
fourth sub-capacitor electrodes below the first sub-capacitor electrodes, and connected to the first sub-capacitor electrodes.

13. The display device of claim 12, wherein the first data line comprises:
a first sub-data line at a same layer as the first sub-capacitor electrodes; and
a second sub-data line at a same layer as the third sub-capacitor electrodes, and connected to the first sub-data line.

14. The display device of claim 12, wherein the second capacitor electrode further comprises:
fifth sub-capacitor electrodes above the second sub-capacitor electrodes, and connected to the second sub-capacitor electrodes; and
sixth sub-capacitor electrodes below the second sub-capacitor electrodes, and connected to the second sub-capacitor electrodes.

15. The display device of claim 14, wherein the third sub-capacitor electrodes and the fifth sub-capacitor electrodes are at a same layer.

16. The display device of claim 14, wherein the fourth sub-capacitor electrodes and the sixth sub-capacitor electrodes are at a same layer.

17. The display device of claim 14, wherein the first capacitor electrode further comprises seventh sub-capacitor electrodes above the third sub-capacitor electrodes, and connected to the third sub-capacitor electrodes,
wherein the first data line comprises:
a first sub-data line at a same layer as the first sub-capacitor electrodes; and
a second sub-data line at a same layer as the third sub-capacitor electrodes, and connected to the first sub-data line.

18. The display device of claim 1, wherein an end of a connection portion where the first sub-capacitor electrodes are connected to each other is above a same straight line as an end of an outermost one of the second sub-capacitor electrodes in plan view.

19. The display device of claim 1, wherein an extension direction of the first sub-capacitor electrodes is parallel to an extension direction of the second sub-capacitor electrodes.

20. An electronic device comprising a display device comprising:
a substrate;
a light-emitting element above the substrate;
a transistor connected to the light-emitting element;
a first node connected to a gate electrode of the transistor; and
a capacitor connected between the first node and a second node, and comprising:
a first capacitor electrode connected to the first node and comprising first sub-capacitor electrodes; and
a second capacitor electrode connected to the second node, and comprising second sub-capacitor electrodes at a same layer as the first sub-capacitor electrodes,
wherein one of the first sub-capacitor electrodes is between adjacent ones of the second sub-capacitor electrodes.
